(19) United States
(12) Patent Application Publication
(10) Pub. No.: US 2025/0060520 A1
(43) Pub. Date: Feb. 20, 2025

(54) OPTICAL FILTER AND UV PIGMENT

(71) Applicant: AGC Inc., Tokyo (JP)

(72) Inventors: Yuichiro ORITA, Fukushima (JP); Kazuhiko SHIONO, Fukushima (JP)

(73) Assignee: AGC Inc., Tokyo (JP)

(21) Appl. No.: 18/938,429

(22) Filed: Nov. 6, 2024

Related U.S. Application Data
(63) Continuation of application No. PCT/JP2023/016177, filed on Apr. 24, 2023.

(30) Foreign Application Priority Data
May 13, 2022 (JP) 2022-079825

(51) Int. Cl. G02B 5/28

(52) U.S. Cl. CPC G02B 5/283

(57) ABSTRACT

An optical filter includes: a substrate; and a dielectric multilayer film laid on or above at least one major surface of the substrate, in which the substrate includes a resin layer, the resin layer includes a transparent resin, a UV dye, and an IR dye that has a maximum absorption wavelength at a wavelength of 650 nm to 800 nm, and the UV dye satisfies all of characteristics (i-1) to (i-4).

### CROSS-REFERENCE TO RELATED APPLICATIONS

This is a bypass continuation of International Patent Application No. PCT/JP2023/016177, filed on Apr. 24, 2023, which claims priority to Japanese Patent Application No. 2022-079825, filed on May 13, 2022. The contents of these applications are hereby incorporated by reference in their entireties.

### TECHNICAL FIELD

The present invention relates to an optical filter and a UV dye. Specifically, the present invention relates to an optical filter that transmits light in a visible wavelength region and shields light in an ultraviolet wavelength region and light in a near-infrared wavelength region. Further, the present invention also relates to a novel UV dye suitable for use as a UV dye in a resin layer in the optical filter.

### BACKGROUND ART

In an imaging device including a solid state image sensor, in order to satisfactorily reproduce a color tone and obtain a clear image, an optical filter that transmits light in a visible region (hereinafter, also referred to as “visible light”) and shields light in an ultraviolet wavelength region (hereinafter, also referred to as “ultraviolet light”) and light in a near-infrared wavelength region (hereinafter, also referred to as “near-infrared light”) is used.

As the optical filter, for example, a reflection type filter is known in which interference of light is used by a dielectric multilayer film in which dielectric thin films having different refractive indices are alternately laid on or above one surface or both surfaces of a transparent substrate, and light desired to be shielded is reflected. In such an optical filter, since an optical film thickness of the dielectric multilayer film is changed according to an incident angle of light, for example, in a case in which light is incident at a high incident angle, a light leak may occur in which near-ultraviolet light that has high reflectance is transmitted. Since an image sensor has sensitivity also in a near-ultraviolet light region, in a case in which a light shielding property of the near-ultraviolet light is not sufficient, an image quality degradation due to unnecessary light called flare or ghost may occur in an acquired visible light image.

Thus, there is a need for a near-infrared light and ultraviolet light cut filter in which spectral sensitivity of the solid state image sensor may not be affected by the incident angle.

Here, Patent Literatures 1 and 2 describe optical filters in which an absorption layer containing a near-ultraviolet light absorbing dye and a near-infrared light absorbing dye in a transparent resin and a dielectric multilayer film are combined, and which has both a near-ultraviolet light cutting ability and a near-infrared light cutting ability.

### CITATION LIST

### Patent Literature

Patent Literature 1: JP6020746B

Patent Literature 2: JP6773161B

### SUMMARY OF INVENTION

However, the optical filters described in Patent Literatures 1 and 2 are designed to shield near-ultraviolet light at incident angles of up to 30 degrees, but there is room for improvement in shielding property at even higher incident angles.

On the other hand, by using a UV dye having a maximum absorption wavelength of about 400 nm, near-ultraviolet light having a wavelength of about 370 nm or more can be shielded. However, if a wavelength is in a range of 350 nm to 370 nm, a light leak still occurs.

Here, when a UV dye having a maximum absorption wavelength of 350 nm to 370 nm in the related art is used, absorption of light in the same wavelength region is weak, and in order to effectively prevent the light leak, it is necessary to add a large amount of the UV dye. Further, an absorption band is broad, and some light in a visible light region, such as a blue band, is also be absorbed.

Therefore, an object of the present invention is to provide an optical filter which has an excellent shielding property of near-infrared light and ultraviolet light while maintaining high visible light transparency, and in particular, prevents flare and ghost by improving a shielding property of ultraviolet light having a wavelength of 350 nm to 370 nm. Another object of the present invention is to provide a UV dye that selectively absorbs ultraviolet light having a wavelength of 350 nm to 370 nm and has an excellent light shielding property.

The present invention provides an optical filter having the following configuration and an imaging device including the optical filter.

An optical filter including:
a substrate; and
a reflection layer including a dielectric multilayer film laid on or above at least one major surface of the substrate as an outermost layer, in which
the substrate includes a resin layer,
the resin layer includes a transparent resin, a UV dye, and an IR dye that has a maximum absorption wavelength at a wavelength of 650 nm to 800 nm, and
the UV dye satisfies all of the following characteristics (i-1) to (i-4):
characteristic (i-1): a maximum absorption wavelength is at a wavelength of 340 nm to 375 nm in dichloromethane,
characteristic (i-2): a molar absorption coefficient in dichloromethane is 3.0×10⁴ L/mol·cm or more,
characteristic (i-3): a half-value width at the maximum absorption wavelength of the characteristic (i-1) is 40 nm or less, and
characteristic (i-4): in a spectral transmittance curve measured by dissolving the UV dye in dichloromethane and adjusting a concentration such that a transmittance at the maximum absorption wavelength of the characteristic (i-1) is 10%, an average transmittance at a wavelength of 350 nm to 370 nm is 20% or less.

Further, the present invention also provides a UV dye having the following configuration.

The UV dye containing a compound represented by the following formula (I)':

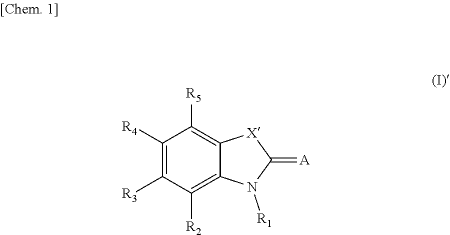

(In the formula (I)′, X′ represents an oxygen atom or a sulfur atom, R¹ represents an alkyl group having 1 to 6 carbon atoms that may have a substituent, R² to R⁵ each independently represent a hydrogen atom, a halogen atom, an alkyl group having 1 to 10 carbon atoms that may have a substituent, an alkoxy group having 1 to 10 carbon atoms that may have a substituent, a nitro group, an amino group, or an amide group, and A represents a divalent group represented by any one of the following formulae (A1) to (A4).

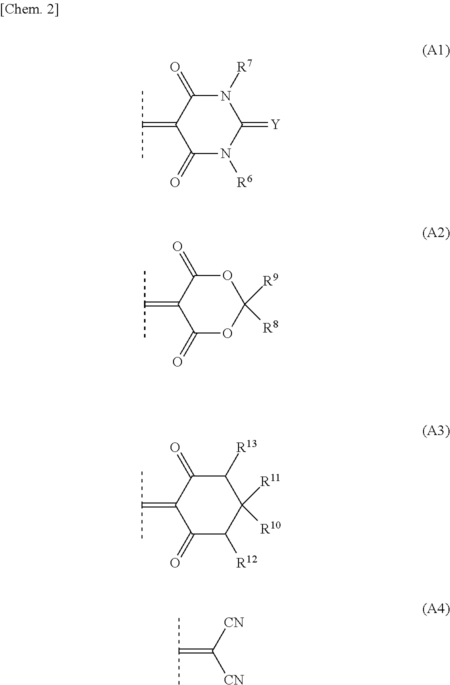

In the formulae (A1) to (A4), Y is an oxygen atom or a sulfur atom, and R⁶ to R¹³ are each independently a hydrogen atom, an alkyl group having 1 to 10 carbon atoms which may have a substituent, or a phenyl group.)

According to the present invention, it is possible to provide an optical filter which has an excellent shielding property of near-infrared light and ultraviolet light while maintaining high visible light transparency, and in particular, prevents flare and ghost by improving a shielding property of the ultraviolet light having a wavelength of 350 nm to 370 nm, and an imaging device including the optical filter. Further, it is possible to provide a UV dye that is suitable for the optical filter, selectively absorbs ultraviolet light having a wavelength of 350 nm to 370 nm, and has an excellent light shielding property.

### BRIEF DESCRIPTION OF DRAWINGS

FIG. 1 is a cross-sectional view schematically illustrating an example of an optical filter according to the present embodiment.

FIG. 2 is a spectral transmittance curve of Example 3-1.

FIG. 3 is a spectral transmittance curve of Example 3-8.

FIG. 4 is a spectral reflectance curve of a substrate in Example 3-1 on an antireflection layer side including a dielectric multilayer film at an incident angle of 5 degrees.

FIG. 5 shows spectral transmittance curves of Example 4-1 at incident angles of 0 degrees, 30 degrees, and 50 degrees.

FIG. 6 shows spectral transmittance curves of Example 4-4 at incident angles of 0 degrees, 30 degrees, and 50 degrees.

FIG. 7 is a spectral reflectance curve of an optical filter in Example 4-1 on a reflection layer side including a dielectric multilayer film at an incident angle of 5 degrees.

### DESCRIPTION OF EMBODIMENTS

Hereinafter, embodiments of the present invention will be described.

In this specification, an “IR dye” means an infrared-light absorbing dye, and a “UV dye” means an ultraviolet-light absorbing dye.

In this specification, spectral characteristics can be measured by using an ultraviolet-visible-near-infrared spectrophotometer.

In the present description, internal transmittance is transmittance obtained by subtracting an influence of interface reflection from measured transmittance, which is represented by a formula {measured transmittance/(100−reflectance)}×100.

In the present description, an absorbance is converted from an (internal) transmittance by a formula of −log₁₀((internal) transmittance/100).

In the present description, a spectrum of transmittance when a dye is contained in a transparent resin are all “internal transmittance” even when described as “transmittance”. On the other hand, transmittance measured by dissolving a dye in a solvent such as dichloromethane, transmittance of a substrate, transmittance of a dielectric multilayer film, and transmittance of an optical filter including the dielectric multilayer film are measured transmittance.

The absorbance and a molar absorption coefficient are calculated by converting the obtained transmission spectral curve into an absorbance curve using the following formula. The same applies to a half-value width at a maximum absorption wavelength.

Absorbance=−log₁₀(transmittance/100)

In the present description, a compound represented by a formula (I) is referred to as a compound (I). The same applies to compounds represented by other formulae. A dye containing the compound (I) is also referred to as a dye (I), and the same applies to other dyes. Further, a group represented by a formula (X1) is also referred to as a group (X1), and the same applies to groups represented by other formulae.

In the present specification, an alkyl group includes either a linear, branched or cyclic alkyl group.

In this specification, the symbol “-” or the word “to” that is used to express a numerical range includes the numerical values before and after the symbol or the word as the upper limit and the lower limit of the range, respectively.

### «Optical Filter»

An optical filter (hereinafter, also referred to as “the optical filter”) according to the present embodiment includes a substrate and a reflection layer including a dielectric multilayer film laid on or above at least one major surface of the substrate as an outermost layer. The substrate includes a resin layer, and such a resin layer includes a transparent resin, and a specific UV dye and a specific IR dye.

With such a configuration, reflection characteristics of the reflection layer including the dielectric multilayer film and absorption characteristics of the dye in the resin layer allow the optical filter as a whole to maintain an excellent transparency in a visible light region and achieve an excellent shielding property in a near-ultraviolet light and near-infrared light region. In particular, when the resin layer contains the UV dye having a specific property, it is possible to effectively shield ultraviolet light having a short wavelength of 350 nm to 370 nm, which has been difficult to prevent from leaking in the related art, without impairing the transparency of the visible light region.

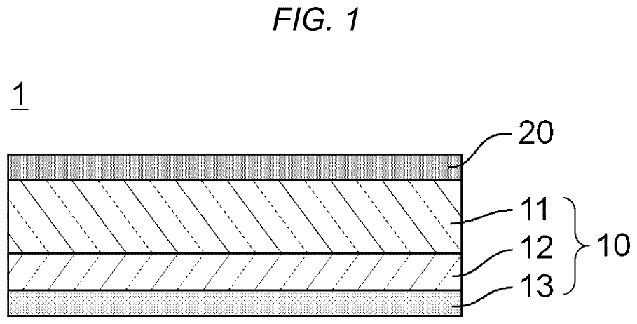

A configuration of the optical filter according to the present embodiment will be described with reference to FIG. 1, which is a cross-sectional view schematically showing an example thereof.

An optical filter 1 includes a substrate 10, and a reflection layer 20 including a dielectric multilayer film on or above a major surface of the substrate 10. The dielectric multilayer film serving as the reflection layer 20 is laid on the outermost layer of the optical filter 1. In FIG. 1, the reflection layer 20 is provided only on or above one major surface of the substrate 10, but may be provided on outermost layers of both major surfaces. Although the reflection layer 20 is illustrated as a single layer in FIG. 1, the reflection layer 20 is actually a dielectric multilayer film in which a plurality of layers including two or more different layers are laid.

The substrate 10 may include a resin layer 12, and the resin layer 12 includes a transparent resin, a specific UV dye, and a specific IR dye.

The substrate 10 may include a support 11 if desired. When the resin layer 12 has a self-supporting property, the resin layer 12 can also function as a support.

When the substrate 10 includes the support 11 and the resin layer 12, the resin layer 12 may be formed on one major surface of the support 11 as shown in FIG. 1, or may be formed on both major surfaces of the support 11 so as to sandwich the support 11 from both sides.

The substrate 10 may include an antireflection layer 13, and when the substrate 10 includes the antireflection layer 13, it is preferable that the antireflection layer 13 be laid on the outermost layer of the optical filter 1 on a side opposite to the reflection layer 20. In FIG. 1, the antireflection layer 13 is illustrated as a single layer, but may be a dielectric multilayer film in which a plurality of layers including two or more different layers are laid.

In addition to the above, the optical filter 1 may further include another functional layer as long as an effect of the present invention is not impaired.

### <Substrate>

### (Resin Layer)

### UV Dye (α)

The UV dye in the present embodiment preferably satisfies all of the following characteristics (i-1) to (i-4), and further satisfies the following characteristics (i-5) and (i-6).

This UV dye may be referred to as a UV dye (α).

Characteristic (i-1): a maximum absorption wavelength is at a wavelength of 340 nm to 375 nm in dichloromethane

Characteristic (i-2): a molar absorption coefficient in dichloromethane is 3.0×10⁴ L/mol·cm or more

Characteristic (i-3): a half-value width at the maximum absorption wavelength of the characteristic (i-1) is 40 nm or less

Characteristic (i-4): in a spectral transmittance curve measured by dissolving the UV dye in dichloromethane and adjusting a concentration such that a transmittance at the maximum absorption wavelength of the characteristic (i-1) is 10%, an average transmittance at a wavelength of 350 nm to 370 nm is 20% or less

Characteristic (i-5): in the spectral transmittance curve measured by dissolving the UV dye in dichloromethane and adjusting the concentration such that the transmittance at the maximum absorption wavelength of the characteristic (i-1) is 10%, a minimum value of a transmittance at a wavelength of 400 nm to 650 nm is 85% or more

Characteristic (i-6): in the spectral transmittance curve measured by dissolving the UV dye in dichloromethane and adjusting the concentration such that the transmittance at the maximum absorption wavelength of the characteristic (i-1) is 10%, the average transmittance at the wavelength of 350 nm to 370 nm is 15% or less

By satisfying the characteristics (i-1) and (i-4), it is possible to shield ultraviolet light

having a wavelength of 350 nm to 370 nm, which has been difficult to prevent from leaking in the related art, and by further satisfying the characteristic (i-2), it is possible to improve such a shielding property, that is, strength of absorbing light.

By satisfying the characteristic (i-3) in addition to the characteristics (i-1), (i-2), and (i-4), it is possible to selectively shield ultraviolet light of a desired wavelength and prevent the light leak without impairing transmittance in a visible light region in which high transparency is required.

In the characteristic (i-1), it is sufficient that the maximum absorption wavelength is in the range of 340 nm to 375 nm, but it is preferable that the maximum absorption wavelength be in the range of 350 nm to 375 nm or 340 nm to 370 nm, and it is more preferable that the maximum absorption wavelength be in a range of 350 nm to 370 nm.

The molar absorption coefficient of the characteristic (i-2) may be 3.0×10⁴ L/mol·cm or more, preferably 3.5×10⁴ L/mol·cm or more, and more preferably 4.0×10⁴ L/mol·cm or more. An upper limit of the molar absorption coefficient is not particularly limited, but is usually 5.0×10⁵ L/mol·cm or less.

The half-value width of the characteristic (i-3) is a wavelength range that is equal to or greater than half the absorbance at the maximum absorption wavelength present in the wavelength of 340 nm to 375 nm in dichloromethane, and is a value that indicates a spread of an absorption peak in a wavelength direction.

The half-value width may be 40 nm or less, but is preferably 38 nm or less, and a lower limit is not particularly limited, but is usually 5 nm or more.

The average transmittance at the wavelength of 350 nm to 370 nm in characteristic (i-4) may be 20% or less, but is preferably 15% or less as shown in the characteristic (i-6). A lower limit of the average transmittance is not particularly limited, and the smaller the lower limit, the more preferable, but the lower limit is usually 0.1% or more.

In addition to the characteristic (i-3), it is preferable that the minimum value of the transmittance at the wavelength of 400 nm to 650 nm in the characteristic (i-5) be 85% or more, since the transmittance in the visible light region at a wavelength of 400 nm to 650 nm, for which high transparency is required, can be maintained without being hindered. The minimum value of the transmittance is more preferably 87.5% or more, further preferably 90% or more, still more preferably 92.5% or more, and particularly preferably 95% or more. The higher the value, the more preferable, and the transmittance may be 100%.

As the UV dye (a) which satisfies the above characteristics (i-1) to (i-4) and preferably further satisfies the above characteristics (i-5) and (i-6), the compound represented by the following formula (I) is preferred.

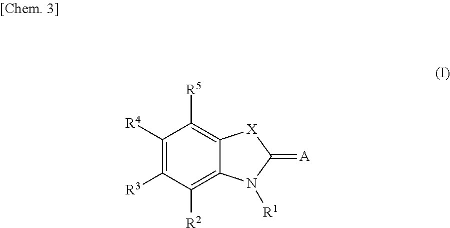

(In the formula (I), X represents an oxygen atom, a sulfur atom, N-R¹⁴, or C-R¹⁵R¹⁶ (R¹⁴ to R¹⁶ each independently represent a hydrogen atom or an alkyl group having 1 to 10 carbon atoms that may have a substituent), R¹ represents an alkyl group having 1 to 6 carbon atoms that may have a substituent, R² to R⁵ each independently represent a hydrogen atom, a halogen atom, an alkyl group having 1 to 10 carbon atoms that may have a substituent, an alkoxy group having 1 to 10 carbon atoms that may have a substituent, a nitro group, an amino group, or an amide group, and A represents a divalent group represented by any one of the following formulae (A1) to (A4).

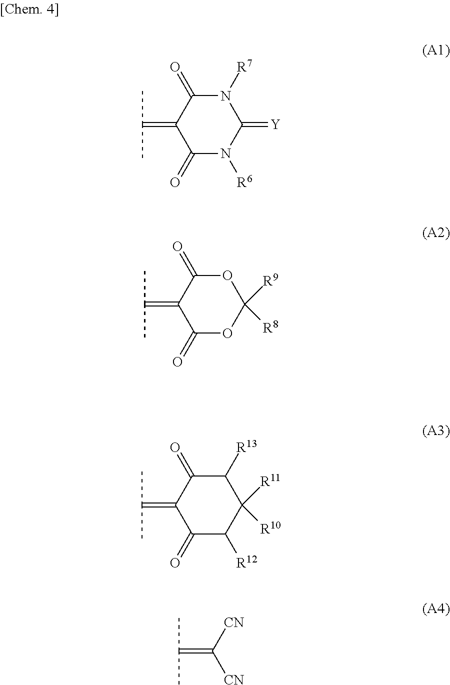

In the formulae (A1) to (A4), Y is an oxygen atom or a sulfur atom, and R⁶ to R¹³ are each independently a hydrogen atom, an alkyl group having 1 to 10 carbon atoms which may have a substituent, or a phenyl group.)

In the compound (I), X is an oxygen atom, a sulfur atom, N-R^{14,} or C-R¹⁵R¹⁶ R¹⁴ to R¹⁶ each independently represent a hydrogen atom or an alkyl group having 1 to 10 carbon atoms which may have a substituent. Examples of the substituent which may be contained include an alkoxy group, an acyl group, an acyloxy group, a cyano group, a dialkylamino group, and a chlorine atom.

It is preferable that R¹⁴ to R¹⁶ each independently represent a hydrogen atom or an alkyl group having 1 to 8 carbon atoms which may have a substituent.

X is preferably an oxygen atom, a sulfur atom, or C-R¹⁵R¹⁶, and more preferably an oxygen atom or a sulfur atom. That is, the compound (I) is more preferably a compound represented by the following formula (I)′.

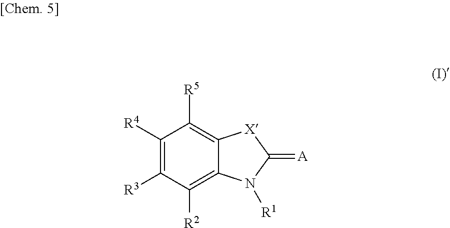

(In the formula (I)′, X′ represents an oxygen atom or a sulfur atom, R¹ represents an alkyl group having 1 to 6 carbon atoms which may have a substituent, R² to R⁵ each independently represent a hydrogen atom, a halogen atom, an alkyl group having 1 to 10 carbon atoms which may have a substituent, an alkoxy group having 1 to 10 carbon atoms which may have a substituent, a nitro group, an amino group, or an amide group, and A represents any one of divalent groups represented by the above formulae (A1) to (A4)).

In the compound (I) or the compound (I)′, R¹ is an alkyl group having 1 to 6 carbon atoms which may have a substituent. Examples of the substituent that may be contained include an alkoxy group, an acyl group, an acyloxy group, a cyano group, a dialkylamino group, and a chlorine atom.

R¹ is preferably an alkyl group having 1 to 6 carbon atoms, more preferably an alkyl group having 1 to 3 carbon atoms, and further preferably a methyl group.

In the compound (I) or the compound (I)′, R² to R⁵ each independently represent a hydrogen atom, a halogen atom, an alkyl group having 1 to 10 carbon atoms which may have a substituent, an alkoxy group having 1 to 10 carbon atoms which may have a substituent, a nitro group, an amino group, or an amide group. Examples of the substituent that may be contained include an alkoxy group, an acyl group, an acyloxy group, a cyano group, a dialkylamino group, and a chlorine atom.

R² is preferably a hydrogen atom, an alkyl group having 1 to 6 carbon atoms, or a halogen atom, and more preferably a hydrogen atom. R³ is preferably a hydrogen atom, an alkyl group having 1 to 6 carbon atoms, or an alkoxy group having 1 to 6 carbon atoms, and more preferably a hydrogen atom or an alkyl group having 1 to 6 carbon atoms. R⁴ is preferably a hydrogen atom, an alkyl group having 1 to 6 carbon atoms, or a halogen atom, and more preferably a hydrogen atom. R⁵ is preferably a hydrogen atom, an alkyl group having 1 to 6 carbon atoms, or a halogen atom, and more preferably a hydrogen atom.

In the compound (I) or the compound (I)′, A represents any one of the divalent groups represented by the above formulae (A1) to (A4), and is preferably a divalent group represented by the formula (A1) or (A3).

In the divalent group represented by the formula (A1), Y is an oxygen atom or a sulfur atom. When X in the formula (I) or X′ in the formula (I)′ is a sulfur atom, Y is preferably an oxygen atom. Further, when Y is a sulfur atom, X is preferably an oxygen atom, N-R¹⁴, or C-R¹⁵R¹⁶, more preferably an oxygen atom, and X′is preferably an oxygen atom.

Furthermore, at least one of X or X′ and Y is preferably an oxygen atom.

In the divalent groups represented by the formulas (A1) to (A4), R⁶ to R¹³ each independently represent a hydrogen atom, an alkyl group having 1 to 10 carbon atoms which may have a substituent, or a phenyl group. Examples of the substituent that may be contained include an alkoxy group, an acyl group, an acyloxy group, a cyano group, a dialkylamino group, and a chlorine atom.

R⁶ and R⁷ each independently preferably represent a hydrogen atom, an alkyl group having 1 to 6 carbon atoms, or a phenyl group, more preferably an alkyl group having 1 to 6 carbon atoms.

R⁸ and R⁹ each independently preferably represent a hydrogen atom, an alkyl group having 1 to 6 carbon atoms, or a phenyl group, and more preferably an alkyl group having 1 to 6 carbon atoms.

R¹⁰ and R¹¹ each independently preferably represent a hydrogen atom, an alkyl group having 1 to 6 carbon atoms, or a phenyl group, and more preferably an alkyl group having 1 to 6 carbon atoms. R¹² and R¹³ each independently represent preferably a hydrogen atom or an alkyl group having 1 to 6 carbon atoms, and more preferably a hydrogen atom.

More specifically, the compound (I) or the compound (I)′ includes compounds in which atoms or groups bonded to each skeleton are shown in Table 1 below. In the table, i-Bu means an isobutyl group, t-Bu means a tertiary butyl group, and Ph means a phenyl group.

TABLE 1

| | | | | | | | | R⁶ | R⁷ | | |
|---|---|---|---|---|---|---|---|---|---|---|---|
| Dye | | | | | | | | R⁸ | R⁹ | Y | |
| abbreviation | R¹ | R² | R³ | R⁴ | R⁵ | X | A | R¹⁰ | R¹¹ | R¹² | R¹³ |
| I-1 | CH₃ | H | H | H | H | S | A1 | CH₃ | CH₃ | O | — |
| I-2 | CH₃ | H | H | H | H | S | A1 | i-Bu | i-Bu | O | — |
| I-3 | CH₃ | H | t-Bu | H | H | O | A1 | C₂H₅ | C₂H₅ | S | — |
| I-4 | CH₃ | H | OCH₃ | H | H | O | A1 | CH₃ | CH₃ | S | — |
| I-5 | CH₃ | H | H | H | H | O | A1 | CH₃ | CH₃ | O | — |
| I-6 | CH₃ | H | H | H | H | S | A1 | Ph | Ph | O | — |
| I-7 | CH₃ | H | H | H | H | S | A2 | CH₃ | CH₃ | — | — |
| I-8 | CH₃ | H | H | H | H | S | A3 | CH₃ | CH₃ | H | H |
| I-9 | CH₃ | H | H | H | H | S | A3 | Ph | H | H | H |
| I-10 | CH₃ | H | H | H | H | S | A4 | — | — | — | — |

Among the above, compounds having dye abbreviations I-1, I-2, I-3, and I-8 are particularly preferred.

The resin layer in the present embodiment may contain one type of UV dye (a) having the above-mentioned characteristics, but this does not exclude inclusion of two or more types thereof.

A method for producing the compound (I) or the compound (I)′ is not particularly limited, and for example, an intermediate 1 represented by the following formula is obtained by reacting 2-(methylthio) benzothiazole and methyl p-toluene sulfonate. In the formula, Ts represents a tosyl group.

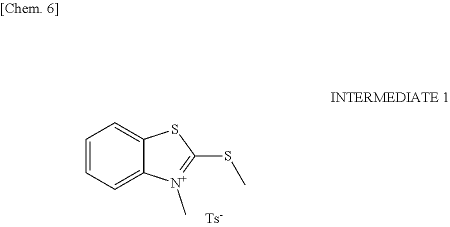

The above-mentioned intermediate 1 is reacted with a compound corresponding to the divalent groups represented by any one of the formulae (A1) to (A4) in the presence of a solvent to obtain the compound (I) or compound (I)′.

Further, by changing the above 2-(methylthio) benzothiazole to a 2-(methylthio) benzothiazole derivative in which hydrogen atoms corresponding to R¹ to R⁵ are changed to substituents, or to a 2-(methylthio) benzoxazole or 2-(methylthio) indole derivative, the compound (I) or compound (I)′ having the desired structure can be obtained.

### UV Dye (β)

The resin layer in the present embodiment may contain another UV dye (β) in addition to the UV dye (α) having the above-described characteristics. The UV dye (β) may have one to three of the characteristics (i-1) to (i-4) of the UV dye (α), or may not have any of the characteristics (i-1) to (i-4).

From the viewpoint of shielding an entire ultraviolet light region having a wavelength of 350 nm to 400 nm, when used in combination with the UV dye (α), the UV dye (β) preferably has a maximum absorption wavelength different from that of the UV dye (α), more preferably has a maximum absorption wavelength on a longer wavelength side than the maximum absorption wavelength of the UV dye (a), and still more preferably has a maximum absorption wavelength at a wavelength of 370 nm to 405 nm.

A difference between the maximum absorption wavelengths of the UV dye (α) and the UV dye (β) is more preferably 15 nm or more, and still more preferably 20 nm or more. An upper limit of the difference between the maximum absorption wavelengths is more preferably 60 nm or less from the viewpoint of shielding the entire ultraviolet light region.

More specifically, the UV dye (β) is preferably a merocyanine dye represented by the following formula (M).

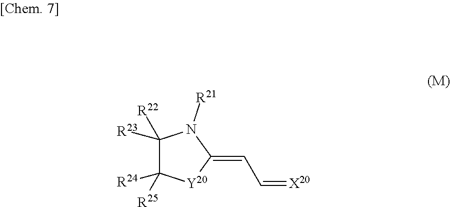

In the formula (M), R²¹ represents a monovalent hydrocarbon group having 1 to 12 carbon atoms which may have a substituent. The substituent is preferably an alkoxy group, an acyl group, an acyloxy group, a cyano group, a dialkylamino group, or a chlorine atom. The above-mentioned alkoxy group, acyl group, acyloxy group and dialkylamino group preferably have 1 to 6 carbon atoms.

Preferred R²¹ is an alkyl group having 1 to 6 carbon atoms in which a part of hydrogen atoms may be substituted with a cycloalkyl group or a phenyl group. Particularly preferred R²¹ is an alkyl group having 1 to 6 carbon atoms, and specific examples thereof include a methyl group, an ethyl group, an n-propyl group, an isopropyl group, an n-butyl group, an isobutyl group, and a t-butyl group.

R²² to R²⁵ each independently represent a hydrogen atom, a halogen atom, an alkyl group having 1 to 10 carbon atoms, or an alkoxy group having 1 to 10 carbon atoms. The alkyl group and the alkoxy group preferably have 1 to 6 carbon atoms, and more preferably 1 to 4 carbon atoms.

At least one of R²² and R²³ is preferably an alkyl group, and both are more preferably alkyl groups. In a case in which R²² and R²³ are not alkyl groups, the two are more preferably hydrogen atoms. Both R²² and R²³ are particularly preferably alkyl groups having 1 to 6 carbon atoms.

At least one of R²⁴ and R²⁵ is preferably a hydrogen atom, and both are more preferably hydrogen atoms. In a case in which R²⁴ and R²⁵ is not a hydrogen atom, an alkyl group having 1 to 6 carbon atoms is preferable.

Y²⁰ represents a methylene group or an oxygen atom substituted with R²⁶ and R²⁷. R²⁶ and R²⁷ each independently represent a hydrogen atom, a halogen atom, an alkyl group having 1 to 10 carbon atoms, or an alkoxy group having 1 to 10 carbon atoms.

X²⁰ represents any one of divalent groups represented by the following formulae (X1) to (X5).

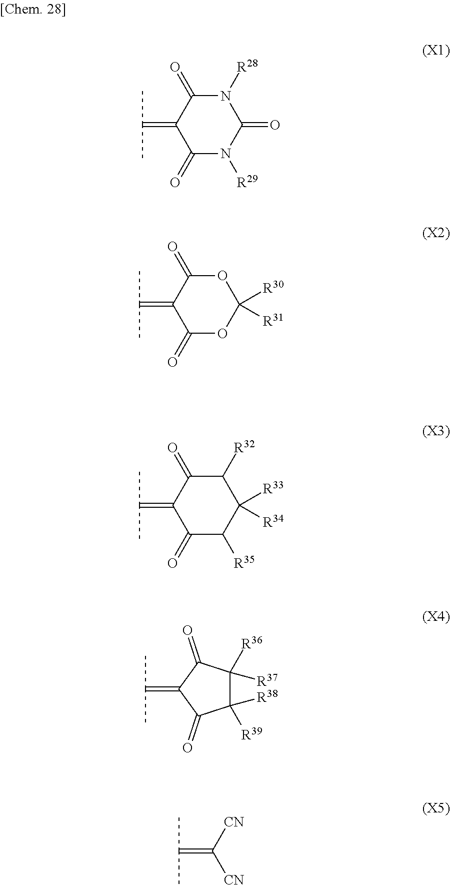

R²⁸ and R²⁹ each independently represent a monovalent hydrocarbon group having 1 to 12 carbon atoms which may have a substituent, and R³⁰ to R³⁹ each independently represent a hydrogen atom or a monovalent hydrocarbon group having 1 to 12 carbon atoms which may have a substituent.

Examples of the substituents of R²⁸ to R³⁹ include the same substituents as the substituent of R²¹, and preferred embodiments thereof are also the same. In a case in which R²⁸ to R³⁹ are hydrocarbon groups which do not have a substituent, examples thereof include the same aspects as those of R²¹ which does not have a substituent.

Preferred R²⁸ and R²⁹ are both alkyl groups having 1 to 6 carbon atoms in which a part of hydrogen atoms may be substituted with a cycloalkyl group or a phenyl group. Particularly preferred R²⁸ and R²⁹ both represent alkyl groups having 1 to 6 carbon atoms, and specific examples thereof include a methyl group, an ethyl group, an n-propyl group, an isopropyl group, an n-butyl group, an isobutyl group, and a t-butyl group.

In the formula (X2), both R³⁰ and R³¹ are more preferably alkyl groups having 1 to 6 carbon atoms, and particularly preferably the same alkyl group.

In the formula (X3), both R³² and R³⁵ are preferably hydrogen atoms or alkyl groups having 1 to 6 carbon atoms which do not have a substituent. Both R³³ and R³⁴, which are two groups bonded to the same carbon atom, are preferably hydrogen atoms or alkyl groups having 1 to 6 carbon atoms.

All of R³⁶ and R³⁷ as well as R³⁸ and R³⁹ in the formula (X4), which are two groups bonded to the same carbon atom, are preferably hydrogen atoms or alkyl groups having 1 to 6 carbon atoms.

A compound represented by the formula (M) is preferably a compound in which Y²⁰ is an oxygen atom and X²⁰ is a group (X1), a group (X2), or a group (X5), or a compound in which Y²⁰ is an unsubstituted methylene group and X²⁰ is a group (X1), a group (X2), or a group (X5).

Specific examples of the compound (M) include compounds shown in the following table.

TABLE 2

| Dye | | R²², | R²⁴, | | | R²⁶, | R²⁸, | R³⁰, |
|---|---|---|---|---|---|---|---|---|
| abbreviation | R²¹ | R²³ | R²⁵ | X²⁰ | Y²⁰ | R²⁷ | R²⁹ | R³¹ |
| (M-1) | CH₃ | H | H | X1 | O | — | CH₃ | — |
| (M-2) | CH₃ | CH₃ | H | X1 | O | — | CH₃ | — |
| (M-3) | C₂H₅ | H | H | X1 | O | — | CH₃ | — |
| (M-4) | C₂H₅ | CH₃ | H | X1 | O | — | CH₃ | — |
| (M-5) | C₃H₇ | H | H | X1 | O | — | CH₃ | — |
| (M-6) | C₃H₇ | CH₃ | H | X1 | O | — | CH₃ | — |
| (M-7) | CH(CH₃)₂ | H | H | X1 | O | — | CH₃ | — |
| (M-8) | CH(CH₃)₂ | CH₃ | H | X1 | O | — | CH₃ | — |
| (M-9) | CH₃ | H | H | X1 | —C(R²⁶)(R²⁷)— | H | CH₂CH(CH₃)₂ | — |
| (M-10) | C₂H₅ | H | H | X1 | —C(R²⁶)(R²⁷)— | H | CH₂CH(CH₃)₂ | — |
| (M-11) | C₃H₇ | H | H | X1 | —C(R²⁶)(R²⁷)— | H | CH₂CH(CH₃)₂ | — |
| (M-12) | CH(CH₃)₂ | H | H | X1 | —C(R²⁶)(R²⁷)— | H | CH₂CH(CH₃)₂ | — |
| (M-13) | CH₃ | CH₃ | H | X2 | O | — | — | CH₃ |
| (M-14) | C₂H₅ | CH₃ | H | X2 | O | — | — | CH₃ |
| (M-15) | C₃H₇ | CH₃ | H | X2 | O | — | — | CH₃ |
| (M-16) | CH(CH₃)₂ | CH₃ | H | X2 | O | — | — | CH₃ |
| (M-17) | CH₃ | H | H | X5 | —C(R²⁶)(R²⁷)— | H | — | — |
| (M-18) | C₂H₅ | H | H | X5 | —C(R²⁶)(R²⁷)— | H | — | — |
| (M-19) | C₃H₇ | H | H | X5 | —C(R²⁶)(R²⁷)— | H | — | — |
| (M-20) | CH(CH₃)₂ | H | H | X5 | —C(R²⁶)(R²⁷)— | H | — | — |

As the compound (M), a compound (M-2), a compound (M-8), a compound (M-9), a compound (M-13), and a compound (M-20) are preferable from the viewpoint that solubility in a transparent resin and a maximum absorption wavelength are appropriate.

The compound (M) can be produced, for example, by a known method described in JP6504176B.

A total content of the UV dye (α) and the UV due (β) in the resin layer is in a range in which a product of the total content of the UV dye (α) and the UV due (β) expressed in mass % and a thickness of the resin layer is preferably 20.0 (mass %·μm) or less, more preferably 19.0 (mass %·μm) or less, and particularly preferably 18.0 (mass %·μm) or less. When the total addition amount of the UV dye (α) and the UV due (β) is within the above range, it is possible to prevent a decrease in resin characteristics and to maintain good adhesion to the dielectric multilayer film or the support. Further, it is possible to prevent a decrease in heat resistance caused by a decrease in a glass transition temperature of the transparent resin.

Further, from the viewpoint of satisfying desired spectral characteristics, the product is preferably 3.0 (mass %·μm) or more, and more preferably 5.0 (mass %·μm) or more.

When the UV dye (α) is used alone, a product of a total content of the UV dye (α) expressed in mass % and the thickness of the resin layer is preferably in the same range as above.

From the viewpoint that the product of the total content of the UV dye (α) and the UV due (β) and the thickness of the resin layer satisfies the above range, a content of the UV dye (α) in the resin layer is preferably 2.0 parts by mass or more, and more preferably 3.0 parts by mass or more, and preferably 15.0 parts by mass or less, and more preferably 14.0 parts by mass or less, with respect to 100 parts by mass of the transparent resin.

For the same reason, when the UV due (β) is contained, a content of the UV due (β) in the resin layer is preferably 2.0 parts by mass or more, and more preferably 3.0 parts by mass or more, and preferably 13.0 parts by mass or less, and more preferably 12.0 parts by mass or less, with respect to 100 parts by mass of the transparent resin.

The total content of the UV dye (α) and the UV due (β) in the resin layer is preferably 4.0 parts by mass or more, and more preferably 5.0 parts by mass or more, and preferably 15.0 parts by mass or less, and more preferably 14.0 parts by mass or less, with respect to 100 parts by mass of the transparent resin.

### IR Dye

The IR dye contained in the resin layer in the present embodiment is a dye having a maximum absorption wavelength of 650 nm to 800 nm. Containing the IR dye can effectively shield infrared light.

The IR dye is preferably at least one selected from the group consisting of a squarylium dye, a cyanine dye, a phthalocyanine dye, a naphthalocyanine dye, a dithiol metal complex dye, an azo dye, a polymethine dye, a phthalide dye, a naphthoquinone dye, an anthraquinone dye, an indophenol dye, a pyrylium dye, a thiopyrylium dye, a croconium dye, a tetradehydrocholine dye, a triphenylmethane dye, an aminium dye, and a diimmonium dye, and more preferably contains at least one dye selected from the group consisting of a squarylium dye, a phthalocyanine dye, and a cyanine dye.

Among these IR dyes, a squarylium dye and a cyanine dye are preferable from a spectroscopic viewpoint, and a phthalocyanine dye is preferable from the viewpoint of durability.

A content of the IR dye in the resin layer is preferably 3 parts by mass or more, and more preferably 5 parts by mass or more, and is preferably 25 parts by mass or less, and more preferably 20 parts by mass or less, with respect to 100 parts by mass of the transparent resin.

### Transparent Resin

The transparent resin contained in the resin layer in the present embodiment is not particularly limited as long as the transparent resin is a transparent resin that transmits visible light having a wavelength of 400 nm to 700 nm.

Examples of the transparent resin include a polyester resin, an acrylic resin, an epoxy resin, an enethiol resin, a polycarbonate resin, a polyether resin, a polyarylate resin, a polysulfone resin, a polyethersulfone resin, a polyparaphenylene resin, a polyarylene ether phosphine oxide resin, a polyamide resin, a polyimide resin, a polyamide-imide resin, a polyolefin resin, a cyclic olefin resin, a polyurethane resin, a polystyrene resin, and the like. These transparent resins may be used alone, or may be used by mixing two or more kinds thereof. Among them, a polyimide resin is preferable from the viewpoint of excellent visible light transmittance a high glass transition temperature of the resin, and resistance to thermal degradation of the dye.

When the transparent resin has self-supporting properties, the transparent resin can also serve as a support, which will be described later. In this case, the substrate according to the present embodiment has a single-layer structure of a resin layer, or a multi-layer structure further including an antireflection layer on one major surface of the resin layer.

### Entire Resin Layer

The resin layer may be provided in the optical filter by one layer or two or more layers. In the case in which the optical filter includes two or more layers of the resin layer, respective resin layers may have the same configuration or different configurations.

The thickness of the resin layer is preferably 3 μm or less, and more preferably 2.5 μm or less, from the viewpoint of obtaining a uniform film having a small film thickness distribution. Further, from the viewpoint of obtaining the desired spectral characteristics, the thickness of the resin layer is preferably 0.5 μm or more, and more preferably 1 μm or more.

When the optical filter according to the present embodiment includes two or more resin layers, the thickness of each resin layer preferably satisfies the above range.

The resin layer preferably satisfies all of the following characteristics (iv-1) to (iv-6). However, it is not essential to satisfy all of the following characteristics.
Characteristic (iv-1): an average internal transmittance (D) at a wavelength of 350 nm to 370 nm is 23% or less
Characteristic (iv-2): an average internal transmittance (E) at a wavelength of 400 nm to 440 nm is 50% or more
Characteristic (iv-3): the average internal transmittance (D) and (E) satisfy a relationship of {(E)/(D)}≥4.0
Characteristic (iv-4): an average internal transmittance (F) at a wavelength of 440 nm to 500 nm is 90% or more
Characteristic (iv-5): an internal transmittance T700 at a wavelength of 700 nm is 5% or less
Characteristic (iv-6): in a spectral internal transmittance curve at a wavelength of 600 nm to 700 nm, a wavelength IR⁵⁰ at which an internal transmittance is 50% is 610 nm to 670 nm

When the resin layer satisfies the above characteristics (iv-1) to (iv-6), it is possible to obtain an optical filter which has a high light shielding property in the near-ultraviolet light region and in which an ultraviolet light shielding property does not decrease even at a high incident angle.

In order to satisfy the above characteristics (iv-1) to (iv-6), for example, the resin layer may contain the above UV dye (α) and IR dye, and it is also preferable to further contain the UV due (β).

The average internal transmittance (D) at the wavelength of 350 nm to 370 nm of the characteristic (iv-1) is 23% or less, and preferably 20% or less. The smaller the better, but the average internal transmittance (D) is usually 1% or more.

The average internal transmittance (E) at the wavelength of 400 nm to 440 nm of the characteristic (iv-2) is 50% or more, and preferably 52% or more. The higher the better, but the average internal transmittance (E) is usually 90% or less.

The ratio {(E)/(D)} of the average internal transmittance (D) and (E) of the characteristic (iv-3) is 4.0 or more, and more preferably 4.3 or more. Further, an upper limit of the above ratio is not particularly limited, but is usually 50 or less.

The average internal transmittance (F) at a wavelength of 440 nm to 500 nm of the characteristic (iv-4) is 90% or more, and more preferably 92% or more. The higher the better, and the average internal transmittance (F) may be 100%.

The internal transmittance T700 at a wavelength of 700 nm of the characteristic (iv-5) is preferably 5% or less, and more preferably 4.5% or less. The lower the better, but the internal transmittance T700 is usually 0.1% or more.

In the spectral internal transmittance curve at a wavelength of 600 nm to 700 nm of the characteristic (iv-6), the wavelength IR⁵⁰ at which the internal transmittance is 50% is 610 nm to 670 nm, and more preferably is 620 nm to 670 nm.

### (Support)

The presence or absence of the support is optional in the resin layer in the present embodiment. The support is not particularly limited and may be made of either an organic material or an inorganic material as long as the material has a self-supporting property and is transparent to visible light of 400 nm to 700 nm.

Further, even when the transparent resin contained in the resin layer has a self-supporting property, a support may be separately provided.

When a support made of an organic material is used, for example, the above-described transparent resin may be used.

When a support made of an inorganic material is used, for example, a glass or a crystalline material is preferable.

The transparent inorganic material is preferably a glass or a crystalline material.

Examples of a glass usable for the support include an absorption type glass, that is, a near infrared ray absorption glass containing copper ions in a fluorophosphate glass, a phosphate glass, or the like, a soda-lime glass, a borosilicate glass, a non-alkali glass, and a quartz glass.

It is preferable to use an absorbing glass according to a purpose as the above glass. For example, from the viewpoint of absorbing the infrared light, a phosphate glass and a fluorophosphate glass are preferable. When it is desired to transmit a large amount of red light having a wavelength of 600 nm to 700 nm, an alkali glass, a non-alkali glass, and a quartz glass are preferable. The “phosphate glass” also includes a silicophosphate glass in which a part of a skeleton of the glass is formed of SiO₂.

A chemically strengthened glass may also be used.

Examples of the crystalline material usable for the support include birefringence crystals such as a crystal, lithium niobate, and sapphire.

The support is preferably made of an inorganic material, and particularly preferably made of a glass or sapphire, from the viewpoint of shape stability related to long-term reliability such as optical characteristics and mechanical characteristics, and from the viewpoint of a handling ability during filter production.

### (Antireflection Layer)

The substrate in the present embodiment may include the antireflection layer on the outermost layer on one side. The antireflection layer means a layer that does not have a wavelength band of 100 nm or more in width at which reflectance is 90% or more in a spectral reflectance curve at a wavelength of 750 nm to 1200 nm and an incident angle of 5 degrees.

Examples of the antireflection layer include a dielectric multilayer film, an intermediate refractive index medium, and a moth-eye structure in which the refractive index gradually changes. Among them, a dielectric multilayer film is preferred from the viewpoint of optical efficiency and productivity.

The dielectric multilayer film is a multilayer film in which dielectric films having a low refractive index, called low refractive index films, and dielectric films having a high refractive index, called high refractive index films, are alternately laid, and any known dielectric films in the related art can be used.

A thickness of the antireflection layer is preferably 0.1 μm or more, and more preferably 0.2 μm or more from the viewpoint of the optical characteristics. Further, from the viewpoint of the productivity, the thickness of the antireflection layer is preferably 1.5 μm or less, and more preferably 1.0 μm or less.

### (Entire Substrate)

The substrate according to the present embodiment preferably satisfies all of the following characteristics (ii-1) to (ii-6). However, it is not essential to satisfy all of the following characteristics:
characteristic (ii-1): an average transmittance (A) at a wavelength of 350 nm to 370 nm is 15% or less,
characteristic (ii-2): an average transmittance (B) at a wavelength of 400 nm to 440 nm is 48% or more,
characteristic (ii-3): the average transmittance (A) and (B) satisfy a relationship of {(B)/(A)} ≥6.0,
characteristic (ii-4): an average transmittance (C) at a wavelength of 440 nm to 500 nm is 88% or more,
characteristic (ii-5): a transmittance T700 at a wavelength of 700 nm is 5% or less, and
characteristic (ii-6): in a spectral transmittance curve at a wavelength of 600 nm to 700 nm, a wavelength IR50 at which a transmittance is 50% is 610 nm to 670 nm.

By satisfying the above characteristics (ii-1) to (ii-6), an optical filter having an excellent near-infrared light and ultraviolet light shielding property while maintaining high visible light transparency can be obtained.

In order to satisfy the above characteristics (ii-1) to (ii-6), for example, the resin layer may contain the above UV dye (α) and IR dye, and it is also preferable to further contain the UV due (β).

The average transmittance (A) at the wavelength of 350 nm to 370 nm of the characteristic (ii-1) is 15% or less, and more preferably 13% or less. The smaller the better, but the average transmittance (A) is usually 1% or more.

The average transmittance (B) at the wavelength of 400 nm to 440 nm of the characteristic (ii-2) is 48% or more, and more preferably 50% or more. The higher the better, but the average transmittance (B) is usually 90% or less.

The ratio {(B)/(A)} of the average transmittance (A) and (B) of the characteristic (ii-3) is 6.0 or more, and more preferably 6.5 or more. Further, an upper limit of the above ratio is not particularly limited, but is usually 50 or less.

The average transmittance (C) at the wavelength of 440 nm to 500 nm of the characteristic (ii-4) is 88% or more, and more preferably 89% or more. The higher the better, and the average transmittance (C) may be 100%. The transmittance T700 at the wavelength of 700 nm of the characteristic (ii-5) is 5%

or less, more preferably 4% or less, and still more preferably 3% or less. The lower the better, but the transmittance T₇₀₀ is usually 0.1% or more.

In the spectral transmittance curve at the wavelength of 600 nm to 700 nm of the characteristic (ii-6), the wavelength IR50 at which the transmittance is 50% is 610 nm to 670 nm, more preferably 620 nm to 670 nm, and still more preferably 630 nm to 670 nm.

The thickness of the substrate is preferably 50 μm or more, and more preferably 70 μm or more from the viewpoint of preventing warpage and deformation when forming the reflection layer including the dielectric multilayer film and from the viewpoint of the handling ability. Further, an upper limit is not particularly limited, but is preferably 300 μm or less, for example. When the resin layer also serves as the support, the thickness of the substrate is more preferably 120 μm or less in view of the advantage of reducing a height. Further, in the case in which the support is provided in addition to the resin layer, the thickness of the substrate is more preferably 110 μm or less.

A shape of the substrate is not particularly limited, and may be, for example, a block shape, a plate shape, or a film shape.

### <Reflection Layer>

The reflection layer in the optical filter according to the present embodiment includes the dielectric multilayer film laid on or above at least one major surface of the substrate as the outermost layer.

The reflection layer means a layer having a wavelength band of 100 nm or more in width at which reflectance is 90% or more in a spectral reflectance curve at a wavelength of 750 nm to 1200 nm and an incident angle of 5 degrees.

The reflection layer preferably has, for example, a wavelength selectivity of transmitting the visible light and mainly reflecting light in the near-infrared region outside a light shielding region of the resin layer. A reflection region of the reflection layer may include a light shielding region in the near-infrared region of the resin layer. The reflection layer is not limited to reflection characteristics of the wavelength of 750 nm to 1200 nm, and may be appropriately designed according to a specification of further shielding a light at a wavelength region other than the near-infrared region, for example, a near-ultraviolet region.

The reflection layer includes a dielectric multilayer film in which a low refractive index film and a high refractive index film are alternately laid.

A refractive index of the high refractive index film is preferably 1.6 or more, more preferably 2.2 or more, and is preferably 2.5 or less. Examples of a material of the high refractive index film include Ta₂O₅, TiO₂, and Nb₂O₅. Among those, TiO₂ is preferable from the viewpoint of reproducibility in film formability and refractive index, stability, and the like.

A refractive index of the low refractive index film is preferably less than 1.6, more preferably less than 1.55, and is preferably 1.45 or more. Examples of a material of the low refractive index film include SiO₂ and SiOₓN_{y}. SiO₂ is preferable from the viewpoint of reproducibility in film formability, stability, economic efficiency, and the like.

It is preferable that transmittance of the reflection layer sharply change in a boundary wavelength region between a transmission region and the light shielding region. In order to sharply change the transmittance, the total number of laid layers of the dielectric multilayer film constituting the reflection layer is preferably 15 or more, more preferably 25 or more, and still more preferably 30 or more. On the other hand, from the viewpoint of preventing an occurrence of warpage or the like and an increase in film thickness, the total number of laid layers is preferably 100 or less, more preferably 75 or less, and still more preferably 60 or less.

The total thickness of the reflection layer is preferably 2 μm or more, and is preferably 10 μm or less.

For formation of the dielectric multilayer film, for example, a vacuum film formation process such as a chemical vapor deposition (CVD) method, a sputtering method, or a vacuum deposition method, a wet film formation process such as a spraying method or a dipping method, or the like can be used.

The reflection layer may provide predetermined optical characteristics by one layer, that is, one group of dielectric multilayer films, or may provide predetermined optical characteristics by two or more layers. When two or more reflection layers, that is, two or more groups of dielectric multilayer films are provided, the reflection layers may have the same configuration or different configurations.

In the case in which two or more reflection layers are provided, it is preferable that the plurality of reflection layers have different reflection bands. For example, a configuration may be adopted in which a near-infrared reflection layer that shields light in a short wavelength band in the near-infrared region and a near-infrared and near-ultraviolet reflection layer that shields light in both a long wavelength band in the near-infrared region and the near-ultraviolet region are combined.

### <Other Functional Layers>

The optical filter according to the present embodiment may further include a functional layer having other functions as another component, as long as the effect of the present invention is not impaired. Examples of the other functional layer includes a functional layer that provides absorption by inorganic fine particles or the like that control transmission and absorption of light in a specific wavelength region.

Examples of the inorganic fine particles include indium tin oxides (ITO), antimony-doped tin oxides (ATO), cesium tungstate, and lanthanum boride. The ITO fine particles and the cesium tungstate fine particles have high visible light transmittance and have light absorbing properties in a wide range of an infrared wavelength region exceeding 1,200 nm, and thus can be used in a case where shielding properties of infrared light are required.

### <Entire Optical Filter>

The optical filter according to the present embodiment preferably satisfies all of the following characteristics (iii-1) to (iii-5). However, it is not essential to satisfy all of the following characteristics.
characteristic (iii-1): a transmittance T700 at a wavelength of 700 nm and an incident angle of 0 degrees is 1% or less,
characteristic (iii-2): in a spectral transmittance curve at a wavelength of 600 nm to 700 nm, an amount of variation at a wavelength IR50 at which a transmittance is 50% between an incident angle of 0 degrees and an incident angle of 30 degrees is 4 nm or less,
characteristic (iii-3): an average transmittance at a wavelength of 350 nm to 370 nm is 0.5% or less at an incident angle of 0 degrees, 0.5% or less at an incident angle of 30 degrees, and 0.5% or less at an incident angle of 50 degrees,
characteristic (iii-4): a maximum transmittance at a wavelength of 350 nm to 370 nm is 5% or less at an incident angle of 0 degrees, 5% or less at an incident angle of 30 degrees, and 5% or less at an incident angle of 50 degrees, and
characteristic (iii-5): an average transmittance at a wavelength of 440 nm to 500 nm is 88% or more at an incident angle of 0 degrees.

By satisfying the above characteristics (iii-1) to (iii-5), an optical filter having an excellent near-infrared light and ultraviolet light shielding property while maintaining high visible light transparency can be obtained.

In order to satisfy the above characteristics (iii-1) to (iii-5), for example, it is sufficient to provide the resin layer containing the above UV dye (α) and the IR dye, and the reflection layer including the dielectric multilayer film, and it is also preferable to provide a resin layer further containing the UV due (β) or to provide an antireflection film.

The transmittance T₇₀₀ at the wavelength of 700 nm and the incident angle of 0 degrees of the characteristic (iii-1) is 1% or less, and is preferably 0.8% or less. The lower the better, and the transmittance T700 may be 0%.

In the spectral transmittance curve at the wavelength of 600 nm to 700 nm of the characteristic (iii-2), the amount of variation of the wavelength IR50 at which the transmittance is 50% between the incident angle of 0 degrees and the incident angle of 30 degrees is 4 nm or less, more preferably 3.5 nm or less, and further preferably 3 nm or less. Further, a lower limit of the amount of variation is not particularly limited, but is usually 0.5 nm or more.

The average transmittance at the wavelength of 350 nm to 370 nm of the characteristic (iii-3) is 0.5% or less at the incident angle of 0 degrees, 0.5% or less at the incident angle of 30 degrees, and 0.5% or less at the incident angle of 50 degrees. At any incident angle, the average transmittance is more preferably 0.4% or less, and still more preferably 0.3% or less. The smaller the better, but the average transmittance is usually 0.01% or more.

The maximum transmittance at the wavelength of 350 nm to 370 nm of the characteristic (iii-4) is 5% or less at the incident angle of 0 degrees, 5% or less at the incident angle of 30 degrees, and 5% or less at the incident angle of 50 degrees. At any incident angle, the maximum transmittance is more preferably 4.5% or less. The smaller the better, but the maximum transmittance is usually 0.1% or more.

The average transmittance at the wavelength of 440 nm to 500 nm of the characteristic (iii-5) is 88% or more at the incident angle of 0 degrees, more preferably 89% or more, still more preferably 92% or more, and particularly preferably 94% or more. The higher the average transmittance, the more preferable, and the average transmittance may be 100%.

For example, in the case in which the optical filter according to the present embodiment is used in an imaging device such as a digital still camera, the optical filter can provide an imaging device having an excellent color reproducibility. That is, the imaging device according to the present embodiment preferably includes the optical filter, and more specifically includes a solid state image sensor, an imaging lens, and the optical filter. The optical filter can be used, for example, by being disposed between the imaging lens and the solid state image sensor, or by being directly attached to the solid state image sensor, the imaging lens, or the like of the imaging device via an adhesive layer.

### <Method for Producing Optical Filter>

The resin layer in the optical filter according to the present embodiment is obtained by dissolving or dispersing, in a solvent, the transparent resin or a raw material component thereof, the UV dye (α), the IR dye, and the UV due (β) and other components, which are blended as necessary, to prepare a coating solution. This is applied to a sheet, heated, and cured to form the resin layer. By peeling off the sheet from the obtained resin layer, a substrate made of only the resin layer is obtained. When the support according to the present embodiment is used for the sheet, a substrate including the support and the resin layer is obtained.

The solvent in the coating solution may be a dispersion medium capable of stably dispersing components or a solvent capable of dissolving the components.

Further, the coating solution may contain a surfactant in order to improve voids due to fine bubbles, depressions due to adhesion of foreign substances and the like, and repelling in a drying process.

For the application of the coating solution, for example, a dip coating method, a cast coating method, or a spin coating method can be used.

The curing is performed by, for example, a curing treatment such as heat curing or photocuring.

When the substrate does not include the support, the resin layer may be produced in a film shape by extrusion molding. Further, even when the substrate includes the support, the resin layer obtained as described above may be integrated with the support by thermocompression bonding or the like.

In addition to the above, if desired, the antireflection layer may be further formed on the substrate.

The reflection layer including the dielectric multilayer film is formed as the outermost layer on or above at least one major surface of the obtained substrate, thereby obtaining the optical filter according to the present embodiment. If desired, other functional layers may be further formed to form the optical filter.

### «UV Dye»

The UV dye according to the present embodiment contains a compound represented by the following formula (I)′.

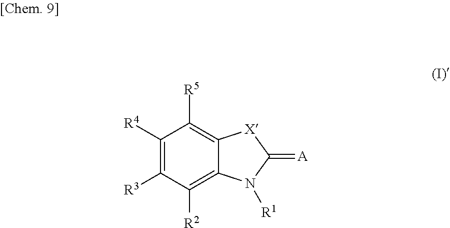

(In the formula (I)′, X′ represents an oxygen atom or a sulfur atom, R¹ represents an alkyl group having 1 to 6 carbon atoms that may have a substituent, R² to R⁵ each independently represent a hydrogen atom, a halogen atom, an alkyl group having 1 to 10 carbon atoms that may have a substituent, an alkoxy group having 1 to 10 carbon atoms that may have a substituent, a nitro group, an amino group, or an amide group, and A represents a divalent group represented by any one of the following formulae (A1) to (A4).

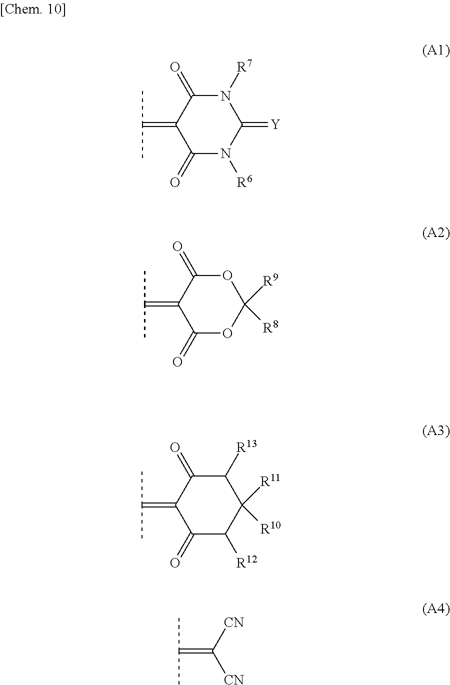

In the formulae (A1) to (A4), Y is an oxygen atom or a sulfur atom, and R⁶ to R¹³ are each independently a hydrogen atom, an alkyl group having 1 to 10 carbon atoms which may have a substituent, or a phenyl group.)

A preferred embodiment of the compound (I)′ is the same as the preferred embodiment of the compound (1)′ described in the. UV dye (α) of the (resin layer) of the <substrate> in the above «optical filter».

The optical filter, the imaging device, and the UV dye according to the present embodiment have been described in detail above. Another aspect of the optical filter and the imaging device according to the present embodiment is as follows.

[1] An optical filter including:
a substrate; and
a dielectric multilayer film laid on or above at least one major surface of the substrate as an outermost layer, in which
the substrate includes a resin layer,
the resin layer includes a transparent resin, a UV dye, and an IR dye that has a maximum absorption wavelength at a wavelength of 650 nm to 800 nm, and
the UV dye satisfies all of the following characteristics (i-1) to (i-4):
characteristic (i-1): a maximum absorption wavelength is at a wavelength of 340 nm to 375 nm in dichloromethane,
characteristic (i-2): a molar absorption coefficient in dichloromethane is 3.0×10⁴ L/mol·cm or more,
characteristic (i-3): a half-value width at the maximum absorption wavelength of the characteristic (i-1) is 40 nm or less, and
characteristic (i-4): in a spectral transmittance curve measured by dissolving the UV dye in dichloromethane and adjusting a concentration such that a transmittance at the maximum absorption wavelength of the characteristic (i-1) is 10%, an average transmittance at a wavelength of 350 nm to 370 nm is 20% or less.

[2] The optical filter according to the [1], in which the UV dye further satisfies the following characteristic (i-5):
characteristic (i-5): in the spectral transmittance curve measured by dissolving the UV dye in dichloromethane and adjusting the concentration such that the transmittance at the maximum absorption wavelength of the characteristic (i-1) is 10%, a minimum value of a transmittance at a wavelength of 400 nm to 650 nm is 85% or more.

[3] The optical filter according to the [1] or [2], in which the UV dye further satisfies the following characteristic (i-6):
characteristic (i-6): in the spectral transmittance curve measured by dissolving the UV dye in dichloromethane and adjusting the concentration such that the transmittance at the maximum absorption wavelength of the characteristic (i-1) is 10%, the average transmittance at the wavelength of 350 nm to 370 nm is 15% or less.

[4] The optical filter according to any one of the [1] to [3], in which the UV dye is a compound represented by the following formula (I):

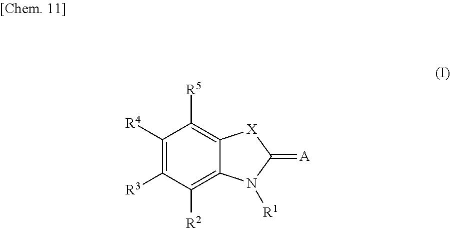

(In the formula (I), X represents an oxygen atom, a sulfur atom, N-R¹⁴, or C-R¹⁵R¹⁶ (R¹⁴ to R¹⁶ each independently represent a hydrogen atom or an alkyl group having 1 to 10 carbon atoms that may have a substituent), R¹ represents an alkyl group having 1 to 6 carbon atoms that may have a substituent, R² to R⁵ each independently represent a hydrogen atom, a halogen atom, an alkyl group having 1 to 10 carbon atoms that may have a substituent, an alkoxy group having 1 to 10 carbon atoms that may have a substituent, a nitro group, an amino group, or an amide group, and A represents a divalent group represented by any one of the following formulae (A1) to (A4):

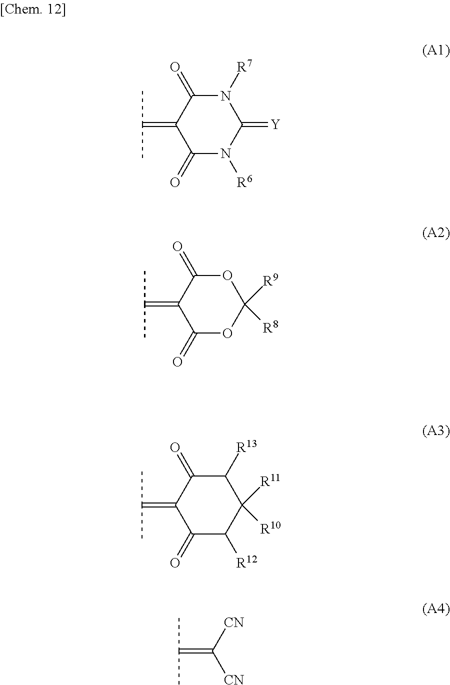

In the formulae (A1) to (A4), Y is an oxygen atom or a sulfur atom, and R⁶ to R¹³ are each independently a hydrogen atom, an alkyl group having 1 to 10 carbon atoms which may have a substituent, or a phenyl group.)

[5] The optical filter according to the [4], in which X is an oxygen atom or a sulfur atom in the compound represented by the formula (I).

[6] The optical filter according to the [4] or [5], in which A is a divalent group represented by the formula (A1) or (A3) in the compound represented by the formula (I).

[7] The optical filter according to any one the [4] to [6], in which A is a divalent group represented by the formula (A1), and at least one of X and Y is an oxygen atom in the compound represented by the formula (I).

[8] The optical filter according to any one the [1] to [7], in which the IR dye is at least one dye selected from the group consisting of a squarylium dye, a phthalocyanine dye, and a cyanine dye.

[9] The optical filter according to any one of the [1] to [8], in which the substrate satisfies all of the following characteristics (ii-1) to (ii-6):
characteristic (ii-1): an average transmittance (A) at a wavelength of 350 nm to 370 nm is 15% or less,
characteristic (ii-2): an average transmittance (B) at a wavelength of 400 nm to 440 nm is 48% or more,
characteristic (ii-3): the average transmittance (A) and (B) satisfy a relationship of {(B)/(A)}≥6.0,
characteristic (ii-4): an average transmittance (C) at a wavelength of 440 nm to 500 nm is 88% or more,
characteristic (ii-5): a transmittance Too at a wavelength of 700 nm is 5% or less, and
characteristic (ii-6): in a spectral transmittance curve at a wavelength of 600 nm to 700 nm, a wavelength IR50 at which a transmittance is 50% is 610 nm to 670 nm.

[10] The optical filter according to any one of the [1] to [9], in which the optical filter satisfies all of the following characteristics (iii-1) to (iii-5):
characteristic (iii-1): a transmittance T70o at a wavelength of 700 nm and an incident angle of 0 degrees is 1% or less,
characteristic (iii-2): in a spectral transmittance curve at a wavelength of 600 nm to 700 nm, an amount of variation at a wavelength IR50 at which a transmittance is 50% between an incident angle of 0 degrees and an incident angle of 30 degrees is 4 nm or less,
characteristic (iii-3): an average transmittance at a wavelength of 350 nm to 370 nm is 0.5% or less at an incident angle of 0 degrees, 0.5% or less at an incident angle of 30 degrees, and 0.5% or less at an incident angle of 50 degrees,
characteristic (iii-4): a maximum transmittance at a wavelength of 350 nm to 370 nm is 5% or less at an incident angle of 0 degrees, 5% or less at an incident angle of 30 degrees, and 5% or less at an incident angle of 50 degrees, and
characteristic (iii-5): an average transmittance at a wavelength of 440 nm to 500 nm is 88% or more at an incident angle of 0 degrees.

[11] An imaging device including:
the optical filter according to any one of the [1] to [10]

### EXAMPLES

Next, the present invention will be described in more detail with reference to examples, but the present invention is not limited to these.

For measurement of each optical characteristic, an ultraviolet-visible-near-infrared spectrophotometer (UH-4150 type, manufactured by Hitachi High-Tech Corporation) was used.

The spectral characteristic in a case in which an incident angle is not particularly specified is a value measured at an incident angle of 0 degrees (in a direction perpendicular to a major surface).

Structures of compounds 1 to 19, which are used as dyes in examples, are as follows, and the compounds are prepared by methods to be described below, respectively. The compounds 1 to 4 are the UV dyes (a), the compounds 5 to 18 are the UV dyes (B), and the compound 19 is the IR dye.

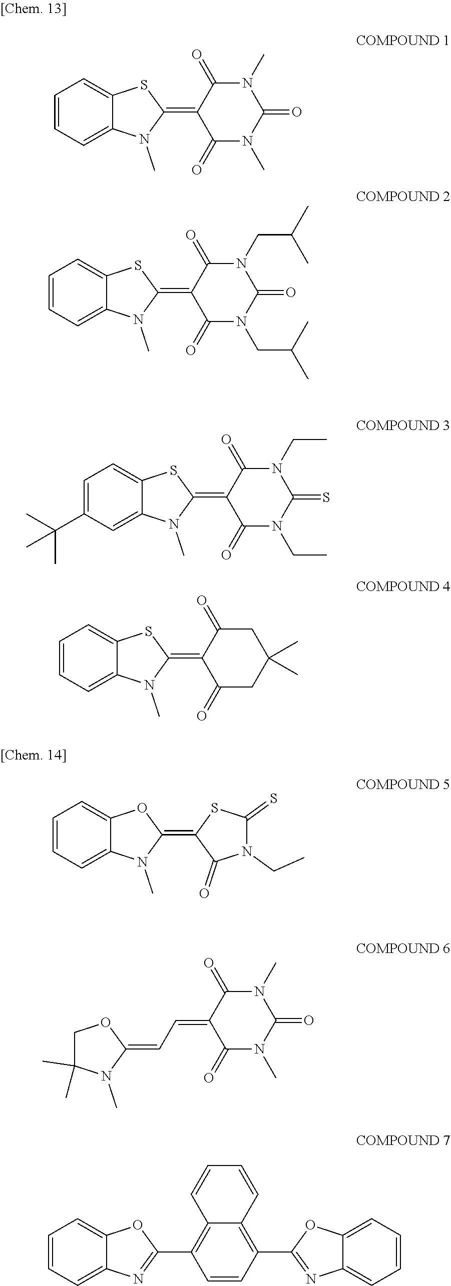

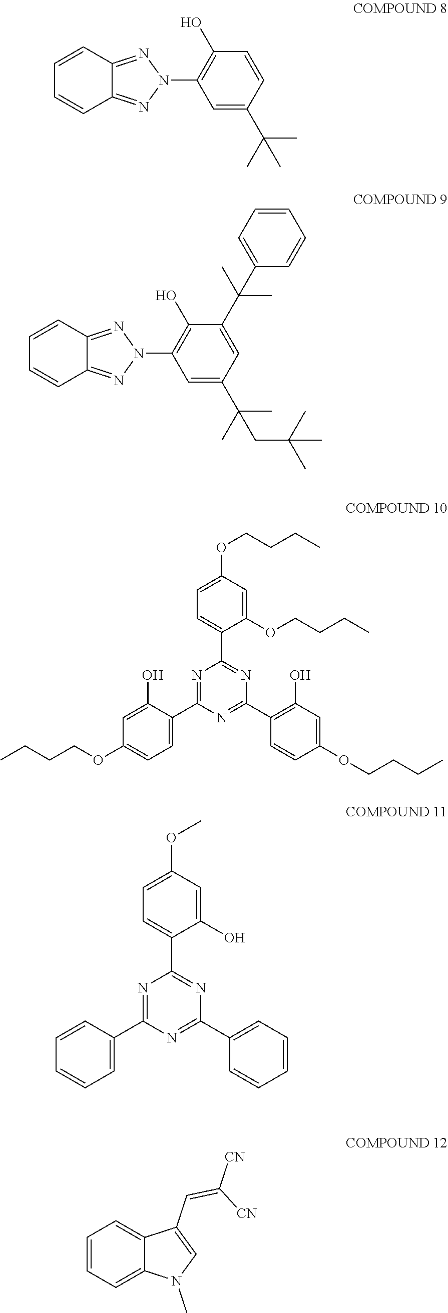

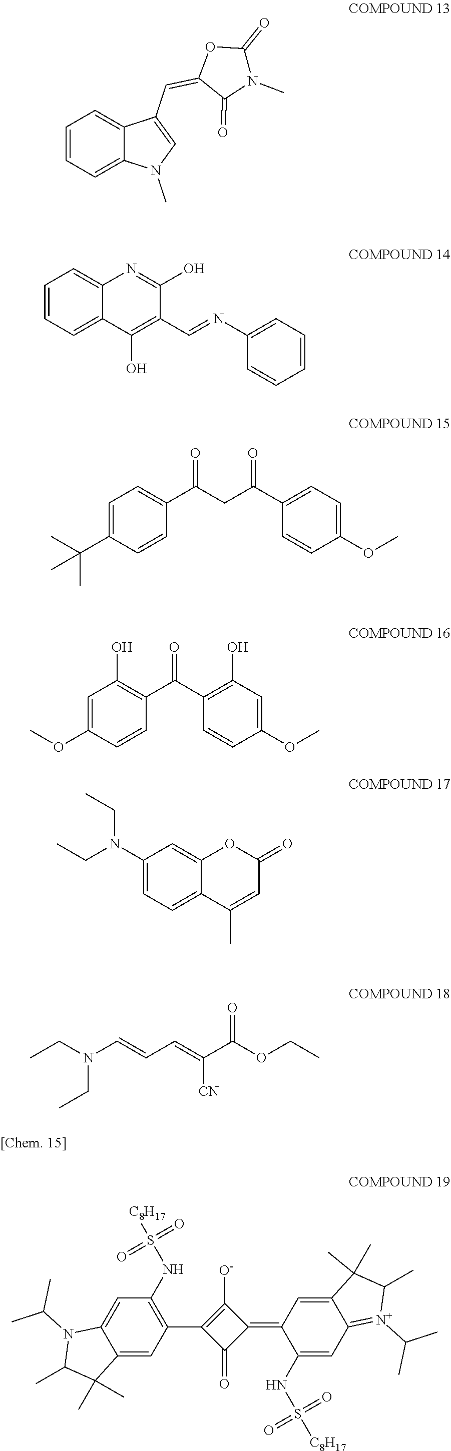

The compounds 1 to 5 were synthesized by methods to be shown below, respectively.

The compound 6 was synthesized with reference to JP6020746B.

B2728 manufactured by Tokyo Chemical Industry Co., Ltd. was used as the compound 7. Tinuvin PS manufactured by BASF Japan Ltd. was used as the compound 8. Tinuvin 928 manufactured by BASF Japan Ltd. was used as the compound 9. Tinuvin 460 manufactured by BASF Japan Ltd. was used as the compound 10.

The compounds 11 to 14 were synthesized with reference to JP6020746B.

B3382 manufactured by Tokyo Chemical Industry Co., Ltd. was used as the compound 15. D0765 manufactured by Tokyo Chemical Industry Co., Ltd. was used as the compound 16. D5730 manufactured by Tokyo Chemical Industry Co., Ltd. was used as the compound 17.

The compound 18 was synthesized with reference to JP2011-184414A. The compound 19 was synthesized with reference to JP6197940B.

### (Synthesis of Compound 1)

### (1) Synthesis of Intermediate 1

2-(methylthio) benzothiazole (25 g) and methyl p-toluenesulfonate (103 g) were placed in a 1 L-sized eggplant flask and reacted at 130° C. for 5 hours. After the reaction was completed, a mixture was returned to room temperature and filtered to obtain an intermediate 1 (50.5 g) shown in the following scheme.

### (2) Synthesis of Compound 1

Next, the intermediate 1 (5.0 g) obtained above, 1,3-dimethylbarbituric acid (2.1 g), triethylamine (2.8 g), and ethanol (130 mL) were placed in a 1 L-sized eggplant flask and reacted at room temperature for 3 hours. After the reaction was completed, a solvent was removed, and a precipitated solid was filtered and washed to obtain the compound 1 (1.5 g).

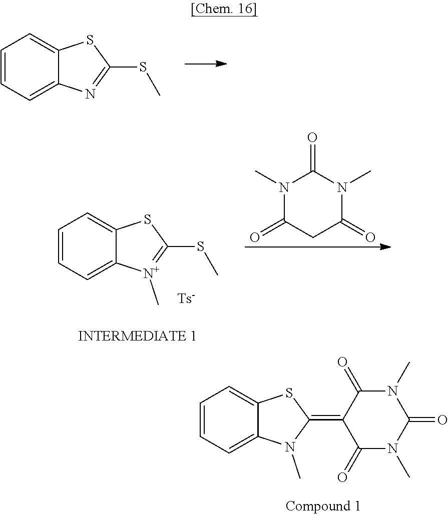 [SMILES: CSc1nc2ccccc2s1 ; CSc1sc2ccccc2[n+]1C ; CN1C(=O)CC(=O)N(C)C1=O ; CN1C(=O)C(=C2Sc3ccccc3N2C)C(=O)N(C)C1=O]

### (Synthesis of Compound 2)

### (1) Synthesis of Intermediate 2

1,1′-carbonyldiimidazole (15 g), isobutylamine (15 g), and N,N-dimethylformamide (DMF, 30 mL) were placed in a 1 L-sized eggplant flask and reacted at 75° C. for 3 hours. After the reaction was completed, a mixture was returned to room temperature, and acidified by adding 1 M aqueous hydrochloric acid, followed by extraction and removal of a solvent to obtain an intermediate 2 (17 g) as shown in the following scheme.

### (2) Synthesis of Intermediate 3

Next, the intermediate 2 (17 g) obtained above, malonic acid (10 g), acetic anhydride (33 g), and acetic acid (100 mL) were added to a 1 L-sized eggplant flask, and a mixture was reacted at 90° C. for 3 hours. After the reaction was completed, a mixture was returned to room temperature, water was added, and a mixture was extracted and then purified with a column to obtain an intermediate 3 (21 g) as shown in the following scheme.

### (3) Synthesis of Compound 2

The compound 2 (2.7 g) was obtained by reacting the intermediate 1 with the intermediate 3 in the same manner as in the (2) synthesis of compound 1, except that the intermediate 3 obtained above was used instead of 1,3-dimethylbarbituric acid in the (2) synthesis of compound 1 in the (synthesis of compound 1).

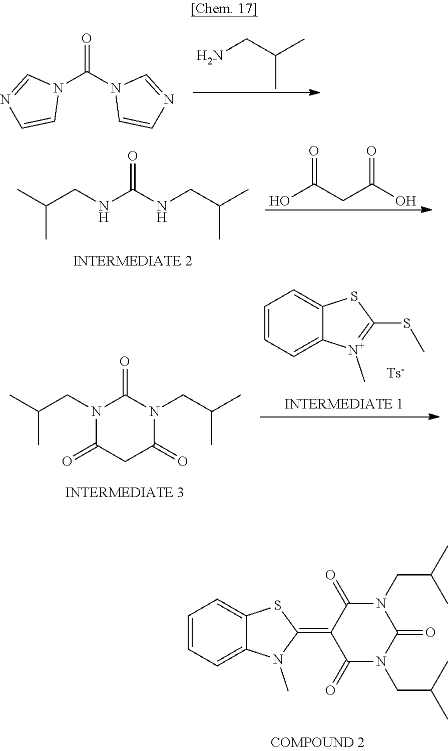

### (Synthesis of Compound 3)

### (1) Synthesis of Intermediate 4

2-amino-4-tert-butylphenol (20 g), tetramethylthiuram disulfide (17.5 g), and water (240 mL) were placed in a 1 L-sized eggplant flask and reacted at 80° C. for 4 hours. After the reaction was completed, a mixture was returned to room temperature, potassium carbonate (33 g) and iodomethane (19 g) were added, and a mixture was reacted at 80° C. for 3 hours. After the reaction was completed, the mixture was returned to room temperature, extracted, and then purified with a column to obtain an intermediate 4 (24 g) shown in the following scheme.

### (2) Synthesis of Intermediate 5

Next, an intermediate 5 (7.4 g) shown in the following scheme was obtained in the same manner as in the (1) synthesis of intermediate 1 in the (synthesis of compound 1), except that the intermediate 4 (5.0 g) was used instead of 2-(methylthio) benzothiazole.

(3) Synthesis of Compound 3

The compound 3 (1.4 g) was obtained in the same manner as in the (2) synthesis of compound 1, except that the intermediate 5 was used instead of the intermediate 1 and 1,3-diethyl-2-thiobarbituric acid was used instead of 1,3-dimethylbarbituric acid in the (2) synthesis of compound 1 of the (synthesis of compound 1).

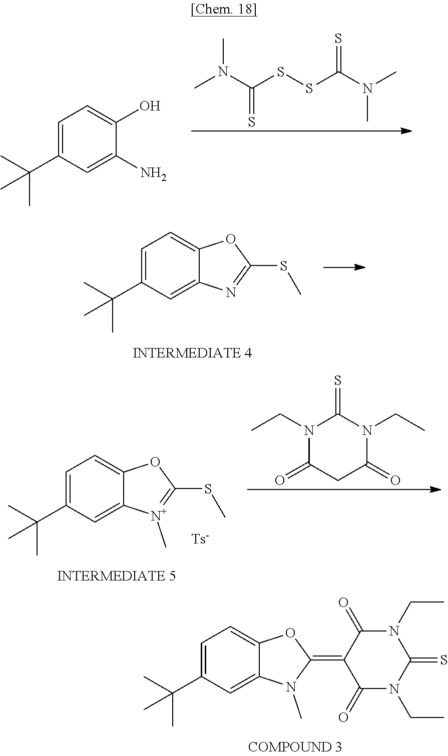

### (Synthesis of Compound 4)

The compound 4 (2.4 g) was obtained in the same manner as in the (2) synthesis of compound 1, except that dimedone was used instead of 1,3-dimethylbarbituric acid in the (2) of synthesis of compound 1 of the (synthesis of compound 1).

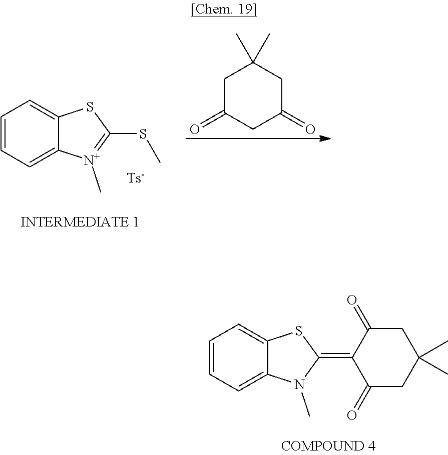

### (Synthesis of Compound 5)

### (1) Synthesis of Intermediate 6

An intermediate 6 (52 g) shown in the following scheme was obtained in the same manner as in the (1) synthesis of intermediate 1, except that 2-(methylthio) benzoxazole was used instead of 2-(methylthio) benzothiazole in the (1) synthesis of intermediate 1 of the (synthesis of compound 1).

### (2) Synthesis of Compound 5

The compound 5 (1.5 g) was obtained in the same manner as in the (2) synthesis of compound 1, except that the intermediate 6 was used instead of the intermediate 1 and 3-ethylrhodanine was used instead of 1,3-dimethylbarbituric acid in the (2) synthesis of compound 1 of the (synthesis of compound 1).

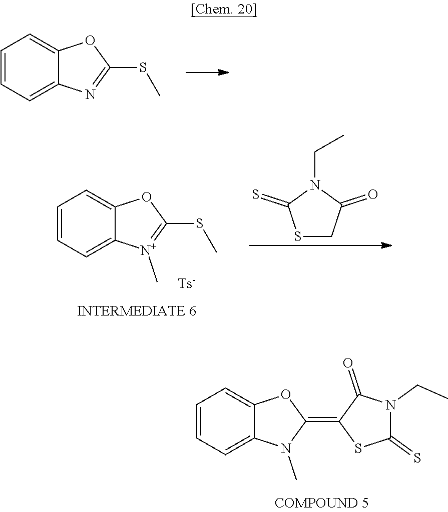

### Examples 1-1 to 1-18

Each of the dyes containing the compounds 1 to 18 shown in Table 3 was dissolved in dichloromethane, and a transmission spectrum was measured in a wavelength range of 300 nm to 900 nm. Concentrations of the compounds 1 to 18 dissolved in dichloromethane were adjusted such that transmittance at a maximum absorption wavelength was 10%.

The obtained transmission spectral curve was converted into an absorbance curve based on a formula, that is, {absorbance=−log₁₀(transmittance/100)} as necessary, and the maximum absorption wavelength, a molar absorption coefficient (×10⁴ L/mol ·cm), a half-value width (nm) at the maximum absorption wavelength, average transmittance at a wavelength of 350 nm to 370 nm, and a minimum value of transmittance at a wavelength of 400 nm to 650 nm were determined. These are summarized in the “λmax (nm)”, “molar absorption coefficient (×10⁴ L/mol·cm)”, “half-value width (nm)”, “average transmittance (350 nm to 370 nm) (%)”, and “minimum transmittance (400 nm to 650 nm) (%)” of Table 3. Examples 1-1 to 1-4 are inventive examples, and Examples 1-5 to 1-18 are comparative examples.

TABLE 3

| | Example | Example | Example | Example | Example | Example | Example | Example | Example |
|---|---|---|---|---|---|---|---|---|---|
| | 1-1 | 1-2 | 1-3 | 1-4 | 1-5 | 1-6 | 1-7 | 1-8 | 1-9 |
| | Com- | Com- | Com- | Com- | Com- | Com- | Com- | Com- | Com- |
| Dye | pound 1 | pound 2 | pound 3 | pound 4 | pound 5 | pound 6 | pound 7 | pound 8 | pound 9 |
| λ max (nm) | 363 | 364 | 353 | 365 | 411 | 396 | 372 | 338 | 346 |
| Molar absorption coefficient | 4.1 | 4.2 | 6.1 | 3.7 | 6.7 | 8.6 | 3.7 | 1.6 | 1.8 |
| (×10⁴ L/mol · cm) | | | | | | | | | |
| Half-value width (nm) | 33 | 34 | 36 | 35 | 37 | 27 | 67 | 63 | 72 |
| Average transmittance | 13.0 | 13.4 | 12.6 | 13.5 | 77.0 | 74.8 | 11.6 | 30.0 | 17.6 |
| (350 nm to 370 nm) (%) | | | | | | | | | |
| Minimum transmittance | 96.1 | 92.7 | 99.3 | 88.5 | 10.0 | 12.2 | 35.4 | 99.3 | 97.0 |
| (400 nm to 650 nm) | | | | | | | | | |
| | Example | Example | Example | Example | Example | Example | Example | Example | Example |
| | 1-10 | 1-11 | 1-12 | 1-13 | 1-14 | 1-15 | 1-16 | 1-17 | 1-18 |
| | Com- | Com- | Com- | Com- | Com- | Com- | Com- | Com- | Com- |
| Dye | pound 10 | pound 11 | pound 12 | pound 13 | pound 14 | pound 15 | pound 16 | pound 17 | pound 18 |
| λ max (nm) | 348 | 339 | 394 | 370 | 376 | 358 | 354 | 371 | 380 |
| Molar absorption coefficient | 7.0 | 2.0 | 2.9 | 2.7 | 2.8 | 3.6 | 2.3 | 2.5 | 5.5 |
| (×10⁴ L/mol · cm) | | | | | | | | | |
| Half-value width (nm) | 63 | 59 | 52 | 51 | 59 | 55 | 62 | 49 | 39 |
| Average transmittance | 21.5 | 39.0 | 42.1 | 12.7 | 14.6 | 11.7 | 12.2 | 12.9 | 24.0 |
| (350 nm to 370 nm) (%) | | | | | | | | | |
| Minimum transmittance | 98.8 | 98.9 | 10.1 | 61.5 | 30.1 | 98.0 | 91.0 | 73.9 | 63.0 |
| (400 nm to 650 nm) (%) | | | | | | | | | |

From the above results, Examples 1-1 to 1-4, which are UV dyes containing the compounds 1 to 4, are of UV dyes (a) that satisfy all of the above characteristics (i-1) to (i-4). These UV dyes (a) can shield ultraviolet light having a wavelength of 350 nm to 370 nm, which has been difficult to prevent from leaking in the related art, and can further improve the shielding property, that is, the strength of absorbing light. Further, it is possible to selectively shield ultraviolet light of the desired wavelength and prevent the light leak while maintaining the transmittance in the visible light region for which high transparency is required.

### Examples 2-1 to 2-13

A polyimide resin (C-3G30G manufactured by Mitsubishi Gas Chemical Company, Inc.) serving as the transparent resin was dissolved in an organic solvent of cyclohexznone:γ-butyrolactone=1:1 (mass ratio) so as to have a concentration of 8.5 mass % to prepare a polyimide resin solution.

To the polyimide resin solution, the compounds described in Table 4 to be UV dyes and the IR dye containing the compound 19 was added in amounts shown in Table 4 with respect to 100 parts by mass of the polyimide resin, and the mixture was stirred at 50° C. for 2 hours to prepare a dye-containing resin solution. This dye-containing resin solution was applied by spin coating to a glass substrate (alkali glass, D263 manufactured by SCHOTT) serving as the support, and heated to obtain a resin layer having a thickness as shown in Table 4.

The glass substrate on which the resin layer was formed was measured by using an ultraviolet-visible-near-infrared spectrophotometer (UH4150, manufactured by Hitachi High-Tech Science Corporation.) to obtain a spectral transmittance curve and a spectral reflectance curve at a wavelength of 350 nm to 1200 nm. Further, the average internal transmittance (D) (%) at the wavelength of 350 nm to 370 nm, the average internal transmittance (E) (%) at the wavelength of 400 nm to 440 nm, the ratio {(E)/(D)} of the above two average internal transmittance, the average internal transmittance (F) (%) at the wavelength of 440 nm to 500 nm, the internal transmittance T700 (%) at the wavelength of 700 nm, and the wavelength IR50 (nm) at which the internal transmittance is 50% in the spectral internal transmittance curve at the wavelength of 600 nm to 700 nm were each determined. These are summarized in the “average internal transmittance (D) (350 nm to 370 nm) (%)”, “average internal transmittance (E) (400 nm to 440 nm) (%)”, “(E)/(D)”, “average internal transmittance (F) (440 nm to 500 nm) (%)”, “internal transmittance T700 (%)”, and “IR50 (nm)” of Table 4. Examples 2-1 to 2-3 and Example 2-13 are inventive examples, and Examples 2-4 to 2-12 are comparative examples.

TABLE 4

| | | Example | Example | Example | Example | Example | Example |
|---|---|---|---|---|---|---|---|
| | | 2-1 | 2-2 | 2-3 | 2-4 | 2-5 | 2-6 |
| UV dye 1 | Compound | Compound 2 | Compound 3 | Compound 4 | Compound 5 | Compound 6 | Compound 7 |
| | Addition amount | 8 | 8 | 8 | 3.6 | 7 | 8 |
| | (parts by mass) | | | | | | |
| UV dye 2 | Compound | | | | | | |
| | Addition amount | | | | | | |
| | (parts by mass) | | | | | | |
| IR dye | Compound | Compound 19 | Compound 19 | Compound 19 | Compound 19 | Compound 19 | Compound 19 |
| | Addition amount | 6 | 6 | 6 | 6 | 6 | 6 |
| | (parts by mass) | | | | | | |

| | | | | | | |
|---|---|---|---|---|---|---|
| Film thickness (μm) | 1.0 | 1.0 | 1.0 | 1.0 | 1.0 | 1.0 |
| Average internal transmittance (D) | 19.8 | 12.8 | 19.6 | 75.4 | 50.0 | 21.3 |
| (350 nm to 370 nm) (%) | | | | | | |
| Average internal transmittance (E) | 88.7 | 89.7 | 87.7 | 47.9 | 55.9 | 74.0 |
| (400 nm to 440 nm) (%) | | | | | | |
| (E)/(D) | 4.5 | 7.0 | 4.5 | 0.6 | 1.1 | 3.5 |
| Average internal transmittance (F) | 97.2 | 97.0 | 97.1 | 96.8 | 96.6 | 97.2 |
| (440 nm to 500 nm) (%) | | | | | | |
| Internal transmittance T₇₀₀ (%) | 3.8 | 3.8 | 3.8 | 3.8 | 3.8 | 3.8 |
| IR50 (nm) | 658.2 | 658.1 | 658.2 | 658.2 | 657.9 | 658.1 |

| | | Example | Example | Example | Example | Example | Example | Example |
|---|---|---|---|---|---|---|---|---|
| | | 2-7 | 2-8 | 2-9 | 2-10 | 2-11 | 2-12 | 2-13 |
| UV dye 1 | Compound | Com- | Com- | Com- | Com- | Com- | Com- | Com- |
| | | pound 9 | pound 10 | pound 13 | pound 14 | pound 16 | pound 18 | pound 4 |
| | Addition amount | 8 | 8 | 8 | 3.6 | 10 | 8 | 5 |
| | (parts by mass) | | | | | | | |
| UV dye 2 | Compound | | | | | | | Com- |
| | | | | | | | | pound 6 |
| | Addition amount | | | | | | | 5 |
| | (parts by mass) | | | | | | | |
| IR dye | Compound | Com- | Com- | Com- | Com- | Com- | Com- | Com- |
| | | pound 19 | pound 19 | pound 19 | pound 19 | pound 19 | pound 19 | pound 19 |
| | Addition amount | 6 | 6 | 6 | 6 | 6 | 6 | 5 |
| | (parts by mass) | | | | | | | |

| | | | | | | | |
|---|---|---|---|---|---|---|---|
| Film thickness (μm) | 1.0 | 1.0 | 1.0 | 1.0 | 1.0 | 1.0 | 1.6 |
| Average internal transmittance (D) | 56.8 | 27.8 | 19.2 | 48.1 | 27.8 | 25.5 | 10.0 |
| (350 nm to 370 nm) (%) | | | | | | | |
| Average internal transmittance (E) | 89.7 | 89.6 | 75.7 | 80.0 | 88.3 | 82.1 | 52.1 |
| (400 nm to 440 nm) (%) | | | | | | | |
| (E)/(D) | 1.6 | 3.2 | 4.0 | 1.7 | 3.2 | 3.2 | 5.2 |
| Average internal transmittance (F) | 97.2 | 97.0 | 97.0 | 97.1 | 97.2 | 97.1 | 95.4 |
| (440 nm to 500 nm) (%) | | | | | | | |
| Internal transmittance T₇₀₀ (%) | 3.8 | 3.8 | 3.8 | 3.8 | 3.8 | 3.8 | 1.3 |
| IR50 (nm) | 658.1 | 658.1 | 658.1 | 658.1 | 658.1 | 658.0 | 645.4 |

From the above results, the resin layers in Examples 2-1 to 2-3 and 2-13 containing the UV dye (α) satisfy all of the above characteristics (iv-1) to (iv-6), and have a high light shielding property in the near-ultraviolet light region, and the light shielding property of the ultraviolet light does not decrease even at a high incident angle. From the results of Example 2-13, it is found that the above-mentioned effect can be obtained even when two kinds of UV dyes corresponding to the UV dye (α) and the UV due (β) are used in combination as the UV dyes.

### Examples 3-1 to 3-8

The glass substrate on which the resin layer in each of Example 2-1, Examples 2-3 to 2-5, Examples 2-9 to 2-11, or Example 2-13 described in Table 5 was formed was used, and an antireflection layer including a dielectric multilayer film in which TiO₂ layers and SiO₂ layers were alternately laid was formed on a surface of the resin layer opposite to the glass substrate, to obtain a substrate.

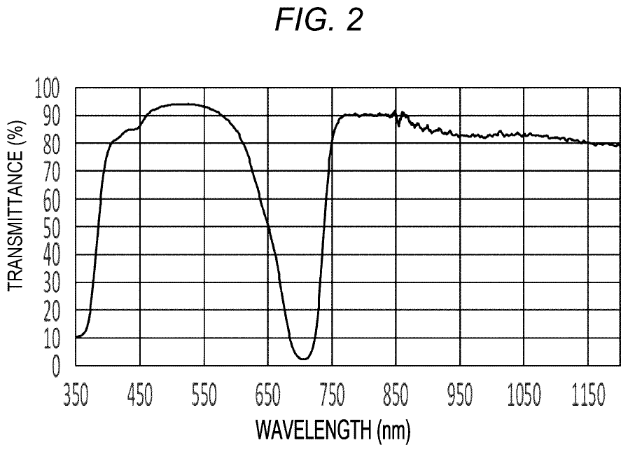

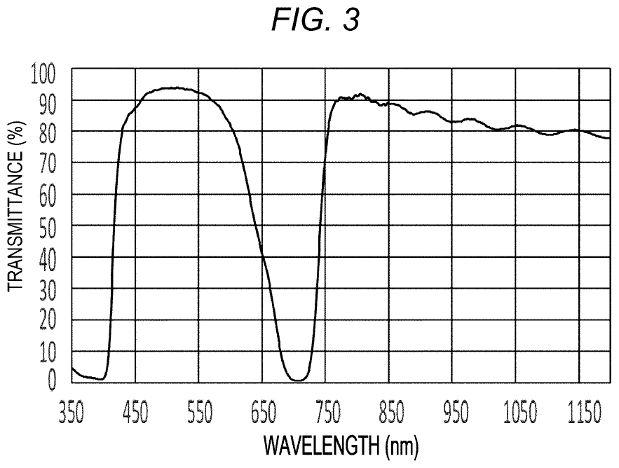

The substrate was measured by using an ultraviolet-visible-near-infrared spectrophotometer (UH4150, manufactured by Hitachi High-Tech Science Corporation.) to obtain a spectral transmittance curve at a wavelength of 350 nm to 1200 nm. Spectral transmittance curves of Examples 3-1 and 3-8 are shown in FIGS. 2 and 3, respectively.

Based on the obtained spectral transmittance curve, the average transmittance (A) (%) at the wavelength of 350 nm to 370 nm, the average transmittance (B) (%) at the wavelength of 400 nm to 440 nm, the ratio {(B)/(A)} of the two average transmittance, the average transmittance (C) (%) at the wavelength of 440 nm to 500 nm, the transmittance T700 (%) at the wavelength of 700 nm, and the wavelength IR50 (nm) at which the transmittance is 50% in the spectral transmittance curve at the wavelength of 600 nm to 700 nm were each determined. These are summarized in the “average transmittance (A) (350 nm to 370 nm) (%)”, “average transmittance (B) (400 nm to 440 nm) (%)”, “(B)/(A)”, “average transmittance (C) (440 nm to 500 nm) (%)”, “transmittance T700 (%)”, and “IR50 (nm)” of Table 5. Examples 3-1, 3-2, and 3-8 are inventive examples, and Examples 3-3 to 3-7 are comparative examples.

Using the above ultraviolet-visible-near-infrared spectrophotometer, a spectral

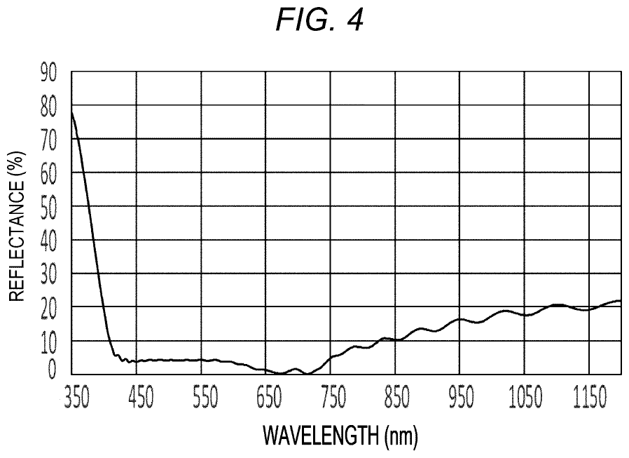

reflectance curve was obtained for an antireflection layer side including the dielectric multilayer film of the substrate in Example 3-1 at an incident angle of 5 degrees. The result is shown in FIG. 4. Since there is no wavelength in a wavelength range of 750 nm to 1200 nm at which reflectance was 90% or more, it is found that such a dielectric multilayer film is an antireflection layer, not a reflection layer. Further, the same dielectric multilayer film as that of the substrate in Example 3-1 is formed in the substrates in Examples 3-2 to 3-8, and therefore the dielectric multilayer films in the substrates of Examples 3-1 to 3-8 are antireflection layers.

TABLE 5

| | Example | Example | Example | Example | Example | Example | Example | Example |
|---|---|---|---|---|---|---|---|---|
| | 3-1 | 3-2 | 3-3 | 3-4 | 3-5 | 3-6 | 3-7 | 3-8 |
| Resin layer | Example | Example | Example | Example | Example | Example | Example | Example |
| | 2-1 | 2-3 | 2-4 | 2-5 | 2-9 | 2-10 | 2-11 | 2-13 |
| UV dye | Compound 2 | Compound 4 | Compound 5 | Compound 6 | Compound 13 | Compound 14 | Compound 16 | Compound |
| | | | | | | | | 4 + 6 |
| Average transmittance (A) | 11.9 | 12.0 | 22.1 | 21.9 | 12.3 | 16.5 | 15.3 | 3.1 |
| (350 nm to 370 nm) (%) | | | | | | | | |
| Average transmittance (B) | 82.5 | 81.9 | 47.3 | 52.5 | 69.7 | 75.0 | 82.9 | 50.1 |
| (400 nm to 440 nm) (%) | | | | | | | | |
| (B)/(A) | 6.9 | 6.8 | 2.1 | 2.4 | 5.7 | 4.5 | 5.4 | 16.2 |
| Average transmittance (C) | 90.6 | 90.6 | 90.8 | 92.0 | 90.4 | 91.2 | 91.5 | 90.9 |
| (440 nm to 500 nm) (%) | | | | | | | | |
| Transmittance T₇₀₀ (%) | 2.5 | 2.6 | 2.6 | 3.0 | 2.5 | 2.4 | 3.4 | 0.8 |
| IR50 (nm) | 650.7 | 650.8 | 650.7 | 650.7 | 650.6 | 649.7 | 653.2 | 639.7 |

From the above results, the substrates in Examples 3-1, 3-2, and 3-8 containing the UV dye (α) satisfy all of the above characteristics (ii-1) to (ii-6), and while maintaining high visible light transparency, have an excellent near-infrared light and ultraviolet light shielding property. Specifically, it can be seen that Examples 3-1 and 3-2 are excellent in light shielding property, particularly in the UV band, and a value represented by {(B)/(A)} is large. Further, from the results of Example 3-8, it is found that the above-mentioned effect can be obtained even when two kinds of dyes corresponding to the UV dye (α) and the UV due (β) are used in combination as the UV dyes.

### Examples 4-1 to 4-4

For each of the substrates in Example 3-1, Example 3-2, Example 3-6, or Example 3-8 described in Table 6, a reflection layer including the dielectric multilayer film in which TiO₂ layers and SiO₂ layers were alternately laid was formed on a surface of the glass substrate opposite to the antireflection layer, to obtain an optical filter.

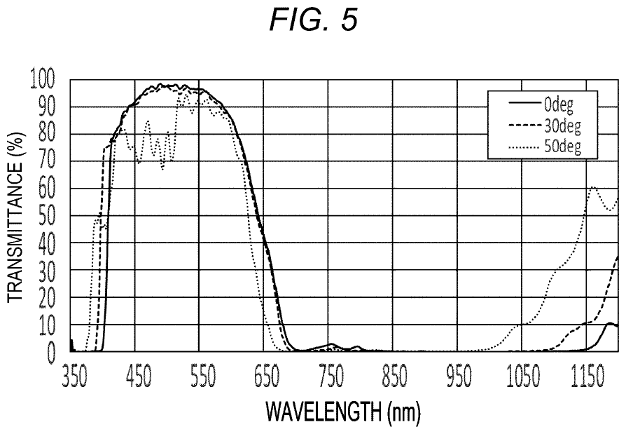

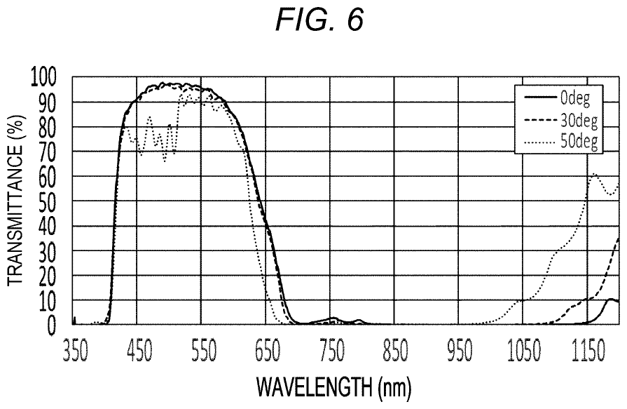

The optical filter was measured by using an ultraviolet-visible-near-infrared spectrophotometer (UH4150, manufactured by Hitachi High-Tech Science Corporation.) to obtain a spectral transmittance curve at a wavelength of 350 nm to 1200 nm. The spectral transmittance curves of Examples 4-1 and 4-4 at incident angles of 0 degrees, 30 degrees, and 50 degrees are shown in FIG. 5 and FIG. 6, respectively.

Based on the obtained spectral transmittance curves, the average transmittance (%) and the maximum transmittance (%) at the wavelength of 350 nm to 370 nm when the incident angle is 0 degrees, 30 degrees, and 50 degrees, the average transmittance (%) at the wavelength of 440 nm to 500 nm when the incident angle is 0 degrees, the transmittance T700 (%) at the wavelength of 700 nm when the incident angle is 0 degrees, and the amount of variation (nm) of the wavelength IR50 at which the transmittance is 50% in the spectral transmittance curve at the wavelength of 600 nm to 700 nm at the incident angle of 0 degrees and an incident angle of 30 degrees were each determined. These are summarized in the “average transmittance (350 nm to 370 nm) (%), incident angle: 0 degrees, incident angle: 30 degrees, incident angle: 50 degrees”, the “maximum transmittance (350 nm to 370 nm) (%) incident angle: 0 degrees, incident angle: 30 degrees, incident angle: 50 degrees”, the “average transmittance (440 nm to 500 nm) (%)”, the “transmittance T700 (%)”, and the “AIR50 (nm)” of Table 6.

Examples 4-1, 4-2, and 4-4 are inventive examples, and example 4-3 is a comparative example.

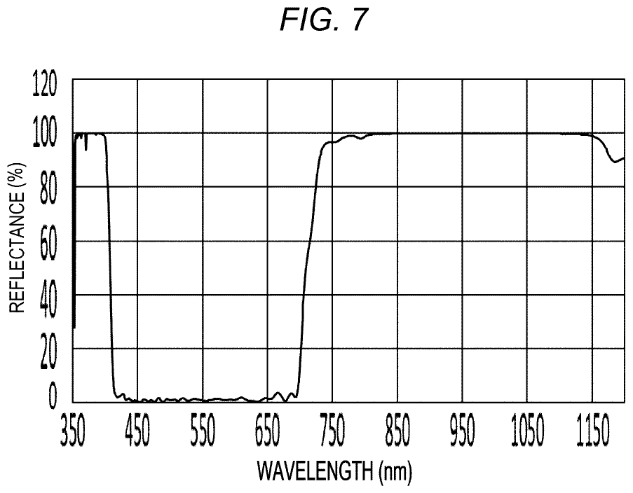

Using the above ultraviolet-visible-near-infrared spectrophotometer, a spectral reflectance curve was obtained for a reflection layer side including the dielectric multilayer film of the optical filter in Example 4-1 at an incident angle of 5 degrees. The result is shown in FIG. 7. in a wavelength range of 750 nm to 1200 nm, a wavelength band at which reflectance is 90% or more continues for 100 nm or more, and thus it is found that such a dielectric multilayer film is a reflection layer. Further, in the optical filters in Examples 4-2 to 4-4, the same dielectric multilayer films as that of the optical filter in Example 4-1 are also formed, and therefore the dielectric multilayer films formed on the outermost layers opposite the antireflection layers in the optical filters of Examples 4-1 to 4-4 are reflection layers.

TABLE 6

| | | Example 4-1 | Example 4-2 | Example 4-3 | Example 4-4 |
|---|---|---|---|---|---|
| Substrate | | Example 3-1 | Example 3-2 | Example 3-6 | Example 3-8 |
| UV dye | | Compound 2 | Compound 4 | Compound 14 | Compound 4 + 6 |
| Average transmittance | Incident angle: 0 degrees | 0.30 | 0.30 | 0.70 | 0.21 |
| (350 nm to 370 nm) (%) | Incident angle: 30 degrees | 0.08 | 0.08 | 0.20 | 0.05 |
| | Incident angle: 50 degrees | 0.16 | 0.15 | 0.40 | 0.10 |
| Maximum transmittance | Incident angle: 0 degrees | 4.29 | 4.31 | 9.80 | 3.18 |
| (350 nm to 370 nm) (%) | Incident angle: 30 degrees | 0.51 | 0.52 | 1.23 | 0.37 |
| | Incident angle: 50 degrees | 0.89 | 0.88 | 2.44 | 0.54 |

| | | | | |
|---|---|---|---|---|
| Average transmittance (440 nm to 500 nm) (%) | 95.3 | 95.2 | 95.3 | 94.6 |
| Transmittance T₇₀₀ (%) | 0.79 | 0.79 | 0.78 | 0.78 |
| ΔIR50 (nm) | 2.7 | 2.8 | 2.7 | 3.1 |

From the above results, the optical filters in Examples 4-1, 4-2, and 4-4 containing the UV dye (α) satisfy all of the above characteristics (iii-1) to (iii-5), and while maintaining high visible light transparency, are particularly excellent in shielding property of a wavelength of 350 nm to 370 nm. Further, from the results of Example 4-4, it is found that the above-mentioned effect can be obtained even when two kinds of dyes corresponding to the UV dye (a) and the UV due (β) are used in combination as the UV dyes.

### Examples 5-1 to 5-4)

The substrates in Examples 3-1 to 3-3, 3-5, and 3-6 shown in Table 7 were irradiated with light from the antireflection layer side, and a light resistance test was performed using a super xenon weather meter (manufactured by Suga Test Instruments Co., Ltd.).

The emitted light has an integral of light of 80000 J/mm² at a wavelength band of 300 nm to 2450 nm. A dye residual ratio was calculated based on the absorbance at the maximum absorption wavelength of the dye before and after the light resistance test according to the following formula. The results are shown in Table 7.

$$dye residual ratio ( \% ) = ( absorbance of maximum absorption wavelength after test / absorbance of maximum absorption wavelength before test ) \times 100$$

TABLE 7

| | Example 5-1 | Example 5-2 | Example 5-3 | Example 5-4 | Example 5-5 |
|---|---|---|---|---|---|
| Substrate | Example 3-1 | Example 3-2 | Example 3-3 | Example 3-5 | Example 3-6 |
| UV dye | Compound 2 | Compound 4 | Compound 5 | Compound 13 | Compound 14 |
| Dye residual ratio | 96% | 96% | 76% | 63% | 59% |

From the above results, it is found that the substrates in Examples 5-1 and 5-2 containing the UV dye (α) are resistant to light and have a very high dye residual ratio.

Although the present invention has been described in detail with reference to specific embodiments, it is apparent to those skilled in the art that various changes and modifications can be made without departing from the spirit and scope of the present invention. The present application is based on a Japanese Patent Application (Japanese Patent Application No. 2022-079825) filed on May 13, 2022, the content of which is incorporated herein by reference.

### REFERENCE SIGNS LIST

1 optical filter

10 substrate

11 support

12 resin layer

13 antireflection layer

20 reflection layer

What is claimed is:

1. An optical filter comprising:
a substrate; and
a dielectric multilayer film laid on or above at least one major surface of the substrate, wherein
the substrate comprises a resin layer,
the resin layer comprises a transparent resin, a UV dye, and an IR dye that has a maximum absorption wavelength at a wavelength of 650 nm to 800 nm, and
the UV dye satisfies all of the following characteristics (i-1) to (i-4):
characteristic (i-1): a maximum absorption wavelength is at a wavelength of 340 nm to 375 nm in dichloromethane,
characteristic (i-2): a molar absorption coefficient in dichloromethane is 3.0×10⁴ L/mol·cm or more,
characteristic (i-3): a half-value width at the maximum absorption wavelength of the characteristic (i-1) is 40 nm or less, and
characteristic (i-4): in a spectral transmittance curve measured by dissolving the UV dye in dichloromethane and adjusting a concentration such that a transmittance at the maximum absorption wavelength of the characteristic (i-1) is 10%, an average transmittance at a wavelength of 350 nm to 370 nm is 20% or less.

2. The optical filter according to claim 1, wherein the UV dye further satisfies the following characteristic (i-5):
characteristic (i-5): in the spectral transmittance curve measured by dissolving the UV dye in dichloromethane and adjusting the concentration such that the transmittance at the maximum absorption wavelength of the characteristic (i-1) is 10%, a minimum value of a transmittance at a wavelength of 400 nm to 650 nm is 85% or more.

3. The optical filter according to claim 1, wherein the UV dye further satisfies the following characteristic (i-6):
characteristic (i-6): in the spectral transmittance curve measured by dissolving the UV dye in dichloromethane and adjusting the concentration such that the transmittance at the maximum absorption wavelength of the characteristic (i-1) is 10%, the average transmittance at the wavelength of 350 nm to 370 nm is 15% or less.

4. The optical filter according to claim 1, wherein the UV dye is a compound represented by the following formula (I): 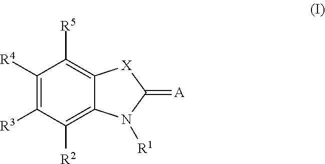
in the formula (I), X represents an oxygen atom, a sulfur atom, N-R¹⁴, or C-R¹⁵R¹⁶ (R¹⁴ to R¹⁶ each independently represent a hydrogen atom or an alkyl group having 1 to 10 carbon atoms that may have a substituent), R¹ represents an alkyl group having 1 to 6 carbon atoms that may have a substituent, R² to R⁵ each independently represent a hydrogen atom, a halogen atom, an alkyl group having 1 to 10 carbon atoms that may have a substituent, an alkoxy group having 1 to 10 carbon atoms that may have a substituent, a nitro group, an amino group, or an amide group, and A represents a divalent group represented by any one of the following formulae (A1) to (A4): 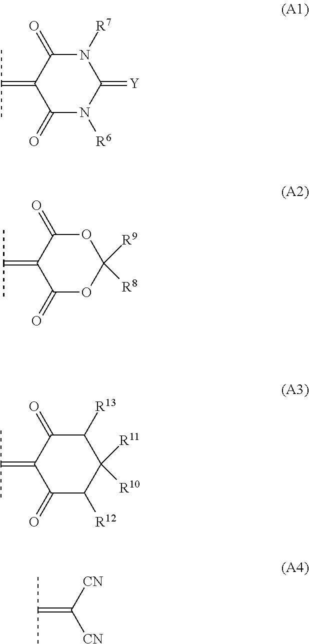
in the formulae (A1) to (A4), Y is an oxygen atom or a sulfur atom, and R⁶ to R¹³ are each independently a hydrogen atom, an alkyl group having 1 to 10 carbon atoms that may have a substituent, or a phenyl group.

5. The optical filter according to claim 4, wherein X is an oxygen atom or a sulfur atom in the compound represented by the formula (I).

6. The optical filter according to claim 4, wherein A is a divalent group represented by the formula (A1) or (A3) in the compound represented by the formula (I).

7. The optical filter according to claim 4, wherein A is a divalent group represented by the formula (A1), and at least one of X and Y is an oxygen atom in the compound represented by the formula (I).

8. The optical filter according to claim 1, wherein the IR dye is at least one dye selected from the group consisting of a squarylium dye, a phthalocyanine dye, and a cyanine dye.

9. The optical filter according to claim 1, wherein the substrate satisfies all of the following characteristics (ii-1) to (ii-6):
characteristic (ii-1): an average transmittance (A) at a wavelength of 350 nm to 370 nm is 15% or less,
characteristic (ii-2): an average transmittance (B) at a wavelength of 400 nm to 440 nm is 48% or more,
characteristic (ii-3): the average transmittance (A) and (B) satisfy a relationship of {(B)/(A)} ≥6.0,
characteristic (ii-4): an average transmittance (C) at a wavelength of 440 nm to 500 nm is 88% or more,
characteristic (ii-5): a transmittance T₇₀₀ at a wavelength of 700 nm is 5% or less, and
characteristic (ii-6): in a spectral transmittance curve at a wavelength of 600 nm to 700 nm, a wavelength IR50 at which a transmittance is 50% is 610 nm to 670 nm.

10. The optical filter according to claim 1, wherein the optical filter satisfies all of the following characteristics (iii-1) to (iii-5):
characteristic (iii-1): a transmittance T₇₀₀ at a wavelength of 700 nm and an incident angle of 0 degrees is 1% or less,
characteristic (iii-2): in a spectral transmittance curve at a wavelength of 600 nm to 700 nm, an amount of variation at a wavelength IR50 at which a transmittance is 50% between an incident angle of 0 degrees and an incident angle of 30 degrees is 4 nm or less,
characteristic (iii-3): an average transmittance at a wavelength of 350 nm to 370 nm is 0.5% or less at an incident angle of 0 degrees, 0.5% or less at an incident angle of 30 degrees, and 0.5% or less at an incident angle of 50 degrees,
characteristic (iii-4): a maximum transmittance at a wavelength of 350 nm to 370 nm is 5% or less at an incident angle of 0 degrees, 5% or less at an incident angle of 30 degrees, and 5% or less at an incident angle of 50 degrees, and
characteristic (iii-5): an average transmittance at a wavelength of 440 nm to 500 nm is 88% or more at an incident angle of 0 degrees.

11. An imaging device comprising:
the optical filter according to claim 1.

12. A UV dye comprising:
a compound represented by the following formula (I)′: 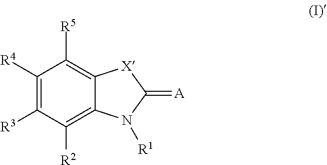
in the formula (I)′, X′ represents an oxygen atom or a sulfur atom, R¹ represents a methyl group or an alkyl group having 3 to 6 carbon atoms, R² to R⁵ each independently represent a hydrogen atom, an alkyl group having 1 to 10 carbon atoms that may have a substituent, a nitro group, an amino group, or an amide group, and A represents a divalent group represented by any one of the following formulae (A1) to (A4): 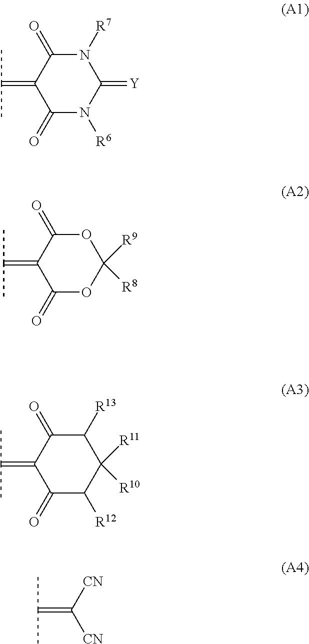
in the formulae (A1) to (A4), Y is an oxygen atom or a sulfur atom, R⁶ represents a hydrogen atom, an alkyl group having 1 to 3 carbon atoms that may have a substituent, an isobutyl group, an alkyl group having 5 to 10 carbon atoms that may have a substituent, or a phenyl group, and R⁷ to R¹³ are each independently a hydrogen atom, an alkyl group having 1 to 10 carbon atoms that may have a substituent, or a phenyl group.
